(19) United States
(12) Patent Application Publication
(10) Pub. No.: US 2016/0036439 A1
(43) Pub. Date: Feb. 4, 2016

(54) SEMICONDUCTOR INTEGRATED CIRCUIT DEVICE

(71) Applicant: Kabushiki Kaisha Toshiba, Tokyo (JP)

(72) Inventor: Toshiaki Douzaka, Yokohama Kanagawa (JP)

(21) Appl. No.: 14/644,156

(22) Filed: Mar. 10, 2015

(30) Foreign Application Priority Data
Jul. 29, 2014 (JP) 2014-154288

(51) Int. Cl. H03K 19/00

(52) U.S. Cl. CPC H03K 19/0013

(57) ABSTRACT

According to one embodiment, a semiconductor integrated circuit device includes a first line to which a voltage is applied; a first circuit operating based on a data; a second circuit capable of retaining the data; a third circuit between the first line and the first circuit and capable of shutting off a supply of the voltage to the first circuit; and a fourth circuit including a resistor element, the resistor element connected between the first line and the second circuit. The fourth circuit supplies the voltage to the second circuit via the resistor element in a period in which the third circuit shut off the supply of the voltage to the first circuit.

### CROSS-REFERENCE TO RELATED APPLICATIONS

This application is based upon and claims the benefit of priority from Japanese Patent Application No. 2014-154288, filed Jul. 29, 2014, the entire contents of which are incorporated herein by reference.

### FIELD

Embodiments described herein relate generally to a semiconductor integrated circuit device.

### BACKGROUND

In recent years, reduction in power consumption of semiconductor integrated circuits has been promoted.

In a method for reducing power consumption of a semiconductor integrated circuit, an operation mode called “sleep mode” is provided in operation modes of the semiconductor integrated circuit. In the sleep mode that is a non-operation period of the circuit, supply of power to the circuit is shut off, thereby reducing the power consumption of the semiconductor integrated circuit.

In the semiconductor integrated circuit to which the sleep mode is applied, supply of power to respective circuits is shut off by a power switch which is disposed between an internal circuit and a power line (or a ground line).

### BRIEF DESCRIPTION OF THE DRAWINGS

FIG. 1 is a view illustrating a basic configuration example of a semiconductor integrated circuit according to an embodiment.

FIG. 2 is a view for describing a configuration example of a semiconductor integrated circuit according to a first embodiment.

FIG. 3 is a view illustrating an example of a data retention circuit included in the semiconductor integrated circuit of the embodiment.

FIG. 4 is a view for describing an operation example of the semiconductor integrated circuit of the first embodiment.

FIG. 5 is a view for describing a modification of the semiconductor integrated circuit of the first embodiment.

FIG. 6 is a view for describing the modification of the semiconductor integrated circuit of the first embodiment.

FIG. 7 is a view for describing a configuration example of a semiconductor integrated circuit according to a second embodiment.

FIG. 8 is a view for describing an operation example of the semiconductor integrated circuit of the second embodiment.

FIG. 9 is a view for describing a configuration example of a semiconductor integrated circuit according to a third embodiment.

FIG. 10 is a view for describing an operation example of the semiconductor integrated circuit of the third embodiment.

FIG. 11 is a view for describing a modification of the semiconductor integrated circuit of the third embodiment.

FIG. 12 is a view for describing the modification of the semiconductor integrated circuit of the third embodiment.

FIG. 13 is a view for describing a configuration example of a semiconductor integrated circuit according to a fourth embodiment.

FIG. 14 is a view for describing an operation example of the semiconductor integrated circuit of the fourth embodiment.

FIG. 15 is a view for describing an operation example of the semiconductor integrated circuit of the fourth embodiment.

FIG. 16 is a view for describing a modification of the semiconductor integrated circuit of the fourth embodiment.

FIG. 17 is a view for describing a modification of the semiconductor integrated circuit of the fourth embodiment.

FIG. 18 is a view for describing the modification of the semiconductor integrated circuit of the fourth embodiment.

FIG. 19 is a view for describing an applied example of the semiconductor integrated circuit of the embodiment.

FIG. 20 is a view for describing an applied example of the semiconductor integrated circuit of the embodiment.

FIG. 21 is a view for describing a modification of the semiconductor integrated circuit of the embodiment.

### DETAILED DESCRIPTION

Various embodiments will now be described in detail with reference to the accompanying drawings. In the description below, elements having the same function and structure are denoted by like reference numerals, and an overlapping description is omitted.

In general, according to one embodiment, a semiconductor integrated circuit device includes: a first power line to which a first voltage is applied; a first circuit operating based on a first data; a second circuit capable of retaining the first data; a third circuit between the first power line and the first circuit and capable of shutting off a supply of the first voltage to the first circuit; and a fourth circuit including a first resistor element, the first resistor element connected between the first power line and the second circuit. The fourth circuit supplies the first voltage to the second circuit via the first resistor element in a first period in which the third circuit shut off the supply of the first voltage to the first circuit.

### EMBODIMENTS

### (A) Basic Embodiment

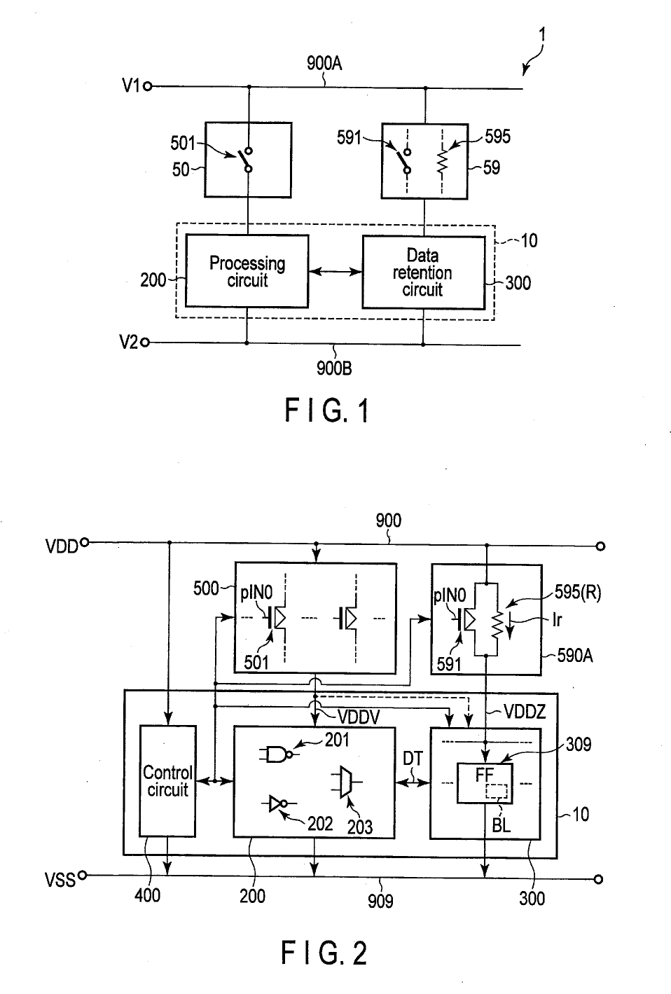

Referring to FIG. 1, a description is given of a basic configuration example of a semiconductor integrated circuit (semiconductor device) according to an embodiment.

As illustrated in FIG. 1, a semiconductor integrated circuit 1 of this embodiment includes an internal circuit 10.

The internal circuit 10 is connected between a first power line (first voltage line) 900A and a second power line (second voltage line) 900B. A first voltage V1 for driving the internal circuit 10 is applied to the first power line 900A, and a second voltage V2 for driving the internal circuit 10 is applied to the second power line 900B. The magnitude of the first voltage V1 differs from that of the second voltage V2.

The internal circuit 10 includes a processing circuit 200 and a data retention circuit 300.

The processing circuit 200 processes a signal from an outside, or a signal generated in the semiconductor integrated circuit 1.

The data retention circuit 300 temporarily retains various data (signals) DT, such as data (setting information) for controlling the processing circuit 200, or data obtained by the processing circuit 200. The data retention circuit 300 includes, for instance, one or more flip-flop circuits. The flip-flop circuit includes one or more latches.

The data DT is input/output between the processing circuit 200 and data retention circuit 300, in accordance with an operation condition of the internal circuit 10.

The semiconductor integrated circuit 1 of the embodiment includes a plurality of operation modes. For example, the semiconductor integrated circuit 1 of the embodiment includes a normal mode and a sleep mode as operation modes.

The normal mode is an operation mode in which a signal process or a calculation process is executed by the processing circuit 200. The sleep mode (also called “standby mode”) is an operation mode in which power (voltage/current) to the processing circuit 200 is shut off and a process by the processing circuit 200 is not executed.

The semiconductor integrated circuit 1 of the embodiment includes a plurality of switch circuits 50, 59. The switch circuit 50, 59 controls the supply of the voltage V1 from the power line 900A to the internal circuit 10.

In accordance with the operation mode of the semiconductor integrated circuit 1, the connection between the power line 900A and internal circuit 10 is switched by ON or OFF of a switch element 501, 591 in the switch circuit 50, 59.

By the switch circuit 50, 59, the semiconductor integrated circuit 1 is driven in the normal mode or in the sleep mode, and the power consumption of the semiconductor integrated circuit 1 is reduced. In the description below, the switch circuit 50, 59, which controls the supply of the voltage to the internal circuit 10, is also referred to as “power switch circuit” (also called “power switch cell”).

The switch circuit 50 is provided between the power line 900A and the processing circuit 200. The switch circuit 59 is provided between the power line 900A and the data retention circuit 300.

The switch circuit 50 includes at least one switch element (also called “power switch”).

At a time (a period TA of a normal mode) of the normal mode of the semiconductor integrated circuit 1, the voltage V1 is applied to the processing circuit 200 via the switch element 501 which is in the ON state.

At a time of the sleep mode of the semiconductor integrated circuit 1, the switch circuit 50 shuts off, by the switch element 501 which is in the OFF state, the supply of the voltage from the power line 900A to the processing circuit 200. Thereby, the voltage V1 is not applied to the processing circuit 200, and the processing circuit 200 enters a non-driven state. Incidentally, at the time of the normal mode, the setting data of the processing circuit 200 may be stored in the processing circuit 200, or may be provided from the data retention circuit 300.

In the present embodiment, the internal configuration of the switch circuit 59, which is associated with the data retention circuit 300, is different from the internal configuration of the switch circuit 50 which is associated with the processing circuit 200.

The switch circuit 59 includes the switch element 591, and a resistor element 595.

In the embodiment, at the time of the sleep mode, the voltage (voltage value) V1 on the power line 900A is applied to the data retention circuit 300 via the resistor element 595 by the switching of the switch element 591.

By the connection between the data retention circuit 300 and the power line 900A via the resistor element 595, there occurs a variation (e.g. voltage drop) of the supply voltage due to the resistor element 595 between the power line 900A and the data retention circuit 300. Thereby, a voltage (voltage value) V1Z, which is less than a potential difference (V1−V2) between the two power lines 900A and 900B, is applied to the data retention circuit 300.

In the semiconductor integrated circuit 1 of the embodiment, at the time of the sleep mode (at the period TB of the non-driven state of the processing circuit 200), the data retention circuit 300 of the semiconductor integrated circuit 1 maintains the data retention state by the voltage V1Z which is less than the voltage (V1−V2). As a result, in the semiconductor integrated circuit 1 of the embodiment, during the period TB of the sleep mode, the occurrence of leak current at the time of the sleep mode (at the time of standby) can be reduced and the power consumption of the data retention circuit 300 can be decreased, compared to the case in which the data retention circuit 300 is driven by the potential difference between the two power lines 900A and 900B.

In the semiconductor integrated circuit 1 of the embodiment, at a time of a restoration operation from the sleep mode to the normal mode, the state of the processing circuit 200 can be re-set by using the data which was stored in the data retention circuit 300 at the time of the sleep mode. Thus, in the semiconductor integrated circuit 1 of the embodiment, the period of the restoration operation of the semiconductor integrated circuit 1 can be shortened.

As has been described above, according to the embodiment, the power consumption of the semiconductor integrated circuit can be reduced, and the speed of the operation of the semiconductor integrated circuit can be increased.

### (B) First Embodiment

Referring to FIG. 2 to FIG. 6, a semiconductor integrated circuit according to a first embodiment is described.

### <B-1> Configuration Example

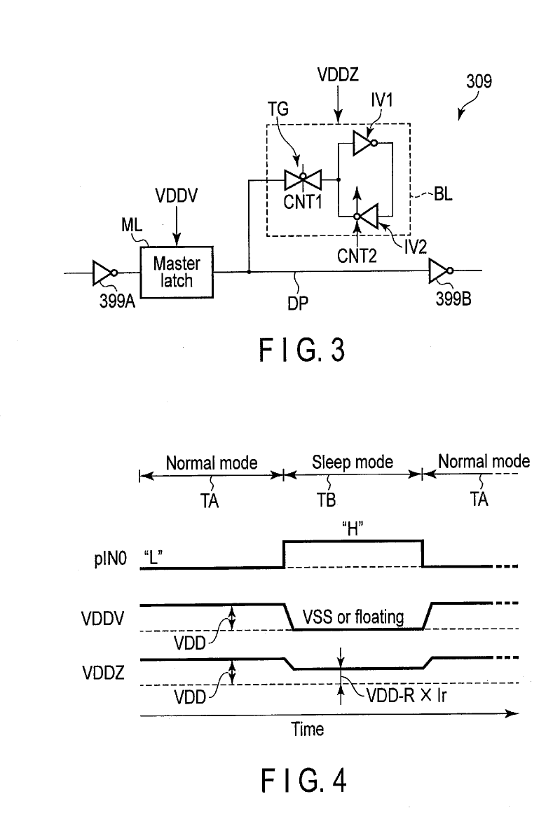

Referring to FIG. 2 and FIG. 3, a configuration example of the semiconductor integrated circuit of the first embodiment is described.

FIG. 2 is a view illustrating a configuration example of a semiconductor integrated circuit 1 of the present embodiment.

The semiconductor integrated circuit (hereinafter referred to as “LSI”) 1 of this embodiment includes an internal circuit 10, and switch circuits 500 and 590A for switching between the normal mode and the sleep mode.

The internal circuit 10 includes a processing circuit 200, a data retention circuit 300 and a control circuit 400.

The processing circuit 200 is, for example, a logic circuit. The logic circuit 200 includes a plurality of elements, such as a logic gate 201, an inverter 202 and a selector 203. The plural elements 201, 202 and 203 are interconnected, thereby forming a circuit which can execute a desired process (e.g. a signal process and/or a calculation process) which is required for the LSI 1. Incidentally, the processing circuit 200 may also be a control circuit, a counter circuit, an inverter circuit, or a memory circuit.

The data retention circuit 300 includes a plurality of flip-flop circuits 309.

Each of the plural flip-flop circuits 309 temporarily retains various data, such as data (signal) calculated by the logic circuit 200, data from the outside of the LSI 1, or setting information of the logic circuit 200 or LSI 1.

The supply of voltage/current is limited by shutoff of power by the power switch which is added, and the power consumption of the LSI 1 at the time of the sleep mode is reduced.

During the sleep mode, since the connection (supply of power) between the circuit and the power supply (or ground line) is shut off, the setting states in the logic circuit 200 and the internal circuit 10 are lost. Thus, at a time of restoration to the operation from the sleep mode, the setting values (setting information) of the logic circuit 200 and internal circuit 10 are re-set. In the case where the setting values of the logic circuit 200 and internal circuit 10 are acquired from the outside of the LSI 1, the period until the logic circuit 200 is restored from the sleep mode to the normal mode becomes longer.

In order to avoid an increase in period of the restoration operation of the logic circuit 200, the flip-flop circuit 309 has a structure (circuit unit) which can retain data at a time of the sleep mode. The flip-flop circuit 309 having such a structure and function is also referred to as “retention FF” in the description below.

In the meantime, at the time of the normal mode, the setting values of the logic circuit 200 and internal circuit 10 may be retained in a storage module (e.g. flip-flop circuit) in the logic circuit 200, or may be provided from the data retention circuit 300 to the logic circuit 200.

FIG. 3 is a view illustrating an example of the flip-flop circuit 309.

For example, the flip-flop circuit 309 includes therein a latch (hereinafter referred to as “master latch”) ML on a data path from an input to an output of the flip-flop circuit 309, and a latch BL which is called “balloon latch”. For example, a plurality of inverters (buffers) 399 may be provided on the data path DP in the flip-flop circuit 309.

Based on a clock signal, for example, the master latch ML takes in data from the logic circuit 200, and outputs data to the logic circuit 200.

The balloon latch BL is connected to the data path DP.

The balloon latch BL is mainly driven at a time of the sleep mode. The balloon latch BL takes in the data of the master latch ML at a time of a transition from the normal mode to the sleep mode. The balloon latch BL continues the retention state of the taken-in data during the sleep mode. At a time of a transition from the sleep mode to the normal mode (at a time of the restoration operation), the balloon latch BL outputs the retained data to the master latch ML or the logic circuit 200.

The data, which is retained by the balloon latch BL at the time of the sleep mode, is the data which is used for the operation at the time of the normal mode of the LSI 1, and is, for instance, setting information of the internal circuit 10 and logic circuit 200.

At the time of the restoration from the sleep mode to normal mode of the LSI 1, the LSI 1 can restore the setting state of the internal circuit 10 to the state prior to the sleep mode, by using the data of the balloon latch BL.

For example, the balloon latch BL includes a transfer gate TG, an inverter IV1, and a three-state inverter IV2.

The transfer gate TG can transfer data in both directions.

One data input/output terminal of the transfer gate TG is connected to the data path DP (output terminal of the master latch ML) in the flip-flop circuit 309.

The other input/output terminal of the transfer gate TG is connected to an input terminal of the inverter IV1 and to an output terminal of the three-state inverter IV2. An output terminal of the inverter IV1 is connected to an input terminal of the three-state inverter IV2. The inverter IV1 and three-state inverter IV2 form a data retention module of the balloon latch BL.

A control signal CNT1 is supplied to a control gate of the transfer gate TG, and thereby the take-in of data on the data path DP and the transfer of data onto the data path DP are controlled.

A control signal CNT2 is supplied to a control gate of the three-state inverter IV2, and thereby data is stored in the data retention module IV1, IV2 of the balloon latch BL. In addition, by the control signal CNT2, the data retention state of the balloon latch BL is reset.

Incidentally, the circuit configuration of the balloon latch BL is not limited to the example illustrated in FIG. 3.

The master latch ML may have, for instance, the same internal configuration as the balloon latch BL. However, a signal for controlling take-in and output of data of the master latch ML is different from the control signal of the balloon latch BL.

The flip-flop circuit 309 may not include the master latch ML and balloon latch BL, and may be composed of only one latch (flip-flop) which can retain data at a time of the sleep mode. Incidentally, the data retention circuit 300 may include a flip-flop circuit (not shown) which does not include the balloon latch BL.

The control circuit 400 controls the operations of the respective circuits 200, 300, 500 and 590A in the LSI 1. Incidentally, the control circuit 400 may be provided outside the LSI 1. In the case where the control circuit 400 is provided outside the LSI 1, the chip (package) of the control circuit 400 is mounted on the same circuit board (e.g. motherboard) as the chip (package) of the LSI 1 of the embodiment.

The internal circuit 10 is connected between a power line 900 on a high potential side and a power line 909 on a low potential side. An external power supply voltage VDD is applied to the power line 900, and a ground voltage VSS is applied to the power line 909. The external power supply voltage is a positive voltage. However, the external power supply voltage may be a negative voltage in accordance with a function of the internal circuit 10 or an internal configuration of the internal circuit 10. Hereinafter, a magnitude (voltage value) of each of voltage is indicated an absolute value.

The logic circuit 200 is connected to the power line 900 via the switch circuit 500. An output voltage VDDV from the switch circuit 500 is applied to the logic circuit 200.

The switch circuit 500 includes one or more switch elements (power switches) 501. The switch element 501 is a p-channel field effect transistor (hereinafter referred to as “p-type transistor”) 501. One end of a current path of the p-type transistor 501 is connected to the power line 900, and the other end of the current path of the p-type transistor 501 is connected to the logic circuit 200 (or elements 201, 202, 203).

The logic circuit 200 is, for example, directly connected to the ground line 909.

The flip-flop circuit 309 is connected to the power line 900 via the switch circuit 590A. An output voltage VDDZ from the switch circuit 590A is applied to the flip-flop circuit 309.

The switch circuit 590A has an internal configuration which is different from the internal configuration of the switch circuit 500.

In the present embodiment, the switch circuit 590A includes a p-type transistor 591 functioning as a power switch, and a resistor element 595. The resistor element 595 is connected in parallel to a current path (source-drain region) of the p-type transistor 591. One end of the current path of the p-type transistor 591 and one end of the resistor element 595 are connected to the power line 900, and the other end of the current path of the p-type transistor 591 and the other end of the resistor element 595 are connected to the flip-flop circuit 309.

By the p-type transistor 591 and resistor element 595 which are connected in parallel to each other, the switch circuit 590A includes two supply paths between the power line 900 and the flip-flop circuit 309 (balloon latch BL).

For example, the gate size of the p-type transistor 591 is the same as that of the p-type transistor 501. The operation property (e.g. current drive ability) of p-type transistor 591 is the same as that of the p-type transistor 501.

The switch circuit 590A is connected to the balloon latch BL of the flip-flop circuit 309. The output voltage VDDZ of the switch circuit 590A is supplied to the power supply terminals of the respective elements which constitute the balloon latch BL.

For example, the master latch ML is connected to the switch circuit 500, and is connected to the power line 900 via the p-type transistor 591, and not via a resistor element. The master latch ML is driven by the output voltage VDDV of the switch circuit 500.

In this manner, the supply path of a voltage (current/power) to the balloon latch BL is different from the supply path of a voltage to the master latch ML.

The flip-flop circuit 309 is, for example, directly connected to the ground line 909.

In the meantime, in accordance with the function which is required for the flip-flop circuit, an arbitrary flip-flop circuit of the plural flip-flop circuits in the master latch 10 may be connected, like the master latch ML, to the power line 900 via the switch circuit 500 which includes no resistor element.

A plurality of flip-flop circuits 309 and a plurality of balloon latches BL may be commonly connected to one switch circuit 590A.

For example, the control circuit 400 is directly connected to the power line 900 and power line 909, without intervention of a switch circuit (power switch).

In the LSI 1 including a normal mode and a sleep mode as operation modes, for example, the control circuit 400 controls switching between the normal mode and sleep mode of the LSI 1, by a command from the outside or a count process of time (clock number) during which no signal from the outside is input.

By a control signal pIN0 from the control circuit 400, the ON/OFF of the switch 501, 591 in the switch circuit 500, 590A is controlled. The control signal pIN0 is applied to the gate of the p-type transistor 501, 591 functioning as a power switch.

At the time of the normal mode, the switch circuits 500 and 590A are activated, and the p-type transistors 501 and 595 are turned on, based on the control signal pIN0.

The switch circuit 500 outputs an internal voltage VDDV to the logic circuit 200. The internal voltage VDDV, which is substantially equal in magnitude to the power supply voltage VDD, is applied to the logic circuit 200 and the respective elements 201, 202, 203, via the p-type transistor 501 which is in the ON state.

The switch circuit 590A outputs an internal voltage VDDZ to the flip-flop circuit 309. For example, the output voltage VDDZ from the switch circuit 590A is supplied to the balloon latch BL, and the balloon latch BL is driven in accordance with the magnitude of the output voltage VDDZ.

At the time of the normal mode, the flip-flop circuit 309 is connected to the power line 900A via the p-type transistor 591 which is in the ON state.

In the switch circuit 590A of FIG. 2, the resistor 595 is connected in parallel to the current path of the transistor 591. If the driving force (current drive ability) of the p-type transistor 591 is sufficiently large when the control signal pIN0 of L (low) level is being applied to the gate, most of the power supply voltage VDD (and current) is supplied to the transistor 591, and supplied to the flip-flop circuit 309 via this transistor 591. Thus, in the present embodiment, the magnitude of the output voltage VDDZ of the switch circuit 590A at the time of the normal mode is substantially equal to the magnitude of the power supply voltage VDD.

At the time of the sleep mode, by the control circuit 400, the p-type transistor 501 is turned off by the control signal pIN0 of H (high) level. The switch circuit 500 electrically isolates the logic circuit 200 from the power line 900.

In this manner, at the time of the sleep mode of the LSI 1, the switch circuit 500 shuts off the supply of the voltage from the power line 900 to the logic circuit 200. By the sleep mode, the logic circuit 200 enters a non-driven state.

In the present embodiment, the state in which the supply of power to the logic circuit 200 is shut off is called “sleep mode”.

For example, the latch (e.g. master latch), which is driven by the output voltage of the switch circuit 500, enters the non-driven state at the time of the sleep mode.

At the time of the sleep mode, the p-type transistor 591 in the switch circuit 590A is turned off by the control signal pIN0 from the control circuit 400. In this case, the voltage/current path in the switch circuit 590 is switched from the transistor side to the resistor element side, and the power supply voltage VDD is applied to the resistor element 595 in the switch circuit 590A.

A voltage drop of the voltage VDD occurs due to the resistor element 595, and the output voltage VDDZ of the switch circuit 590A becomes less than the power supply voltage VDD.

Specifically, when the resistance value of the resistor element 595 is indicated by “R” and the current (current value) flowing in the resistor element 595 is indicated by “Ir”, the output voltage VDDZ of the switch circuit 590A at the time of the sleep mode is VDD−R×Ir.

In the description below, in some cases, for the purpose of distinguishable denotation, the output voltage (internal voltage) of the switch circuit 590A at the time of the normal mode is denoted by nVDDZ, and the output voltage of the switch circuit 590A at the time of the sleep mode is denoted by sVDDZ.

The voltage sVDDZ (VDD−R×Ir), which is applied to the balloon latch BL of the flip-flop circuit 309 at the time of the sleep mode, is equal to or greater than a driving voltage (threshold voltage) Vth of the balloon latch BL.

Therefore, at the time of the sleep mode, even if the logic circuit 200 is not being driven, the balloon latch BL is driven. During the period of the sleep mode, the balloon latch BL can continue the retention of the data (e.g. setting information) which is to be used in the logic circuit 200 after the release of the sleep mode.

In the meantime, the magnitude of the voltage drop of the supply voltage due to the resistor element 595 is determined by the magnitude of the resistance value of the resistor element 595 and the current consumption (leak current) at the time of the sleep mode of the balloon latch BL which is connected to the switch circuit 590A. Thus, when one switch circuit 590A is connected to a plurality of retention FFs (balloon latches BL), the magnitude of the resistance value R of the resistor element 595 is adjusted in accordance with the number of balloon latches BL, which are connected to the switch circuit 590A, and the circuit configuration of the balloon latches. A plurality of resistor elements 595 may be provided in the switch circuit 590A in order to adjust the voltage drop amount/resistance value corresponding to the number of balloon latches BL and the circuit configuration of the balloon latches.

As described above, in the LSI 1 of the present embodiment, re-setting of the internal circuit 10 and logic circuit 200 is executed by using the stored data of the balloon latch BL which is being driven at the time of the sleep mode. Thereby, the speed of the restoration operation of the LSI from the sleep mode to the normal mode can be increased.

In order for the balloon latch to retain, during the period of the sleep mode, the data which is to be used for the restoration operation of the logic circuit, the supply of power to the balloon latch cannot be shut off, and the state of electrical conduction between the balloon latch and the power lines 900 and 909 is maintained. Thus, when a large number of flip-flop circuits, such as balloon latches, which can retain data at a time of the sleep mode, are used in the LSI 1, a leak current corresponding to the magnitude of the supply voltage occurs in each flip-flop circuit, and power consumption of an amount corresponding to the number of flip-flop circuits occurs at the time of the sleep mode. Thus, it is possible that the standby power (the power consumption at the time of the sleep mode) of the LSI 1 increases.

In the present embodiment, by the resistor element 595 in the switch circuit 590A, the voltage sVDDZ, which is applied to the balloon latch BL (flip-flop circuit 309) at the time of the sleep mode, is set to be less than the power supply voltage VDD.

Thus, in the LSI 1 of the present embodiment, even if the balloon latch BL, which retains the data that is to be used in the restoration operation, is being driven at the time of the sleep mode, the leak current occurring at the time of the sleep mode can be reduced, compared to the case in which the balloon latch is driven by the power supply voltage VDD, and an excessive increase in standby power can be suppressed.

In addition, a general LSI includes a regulator with a relatively large circuit scale, as a circuit for supplying power to a flip-flop circuit, such as a balloon latch, which retains data at a time of a sleep mode.

On the other hand, the semiconductor integrated circuit of the embodiment employs the resistor element 595 provided in the switch circuit 590A, in order to supply a voltage to the balloon latch BL at the time of the sleep mode. Therefore, the LSI of the embodiment can achieve, with a relatively small circuit scale, the driving of the balloon latch and the reduction in power consumption at the time of the sleep mode.

As a result, the LSI of the embodiment can suppress an increase in chip cost.

As has been described above, according to the semiconductor integrated circuit of the embodiment, the power consumption at the time of the standby state can be reduced, and the speed of the restoration operation from the standby state can be increased.

### <B-2> Operation

Referring to FIG. 4, the operation of the semiconductor integrated circuit (LSI) of the first embodiment is described. In this description, FIG. 2 and FIG. 3 are also referred to, where necessary, and the operation of the LSI of the embodiment is described.

FIG. 4 is a timing chart of respective signals and respective voltages for describing an operation example of the LSI of the present embodiment.

As illustrated in FIG. 4, at the time of the normal mode of the LSI 1 of FIG. 2, the control circuit 400 supplies a control signal pIN0 of L (low) level to the switch circuit 500, 590A. By the control signal pIN0, each p-type transistor 501, 595 in the switch circuit 500, 590A is turned on. The logic circuit (processing circuit) 200, the data retention circuit 300 and the flip-flop circuit 309 in the data retention circuit 300 are connected to the power line 900 via the p-type transistors 501 and 591, which are in the ON state, in the switch circuits 500 and 590A.

The output voltage VDDV of the switch circuit 500 is supplied to the logic circuit 200, and the logic circuit 200 is driven by the voltage VDDV (=VDD).

The output voltage VDDZ of the switch circuit 590A is supplied to the flip-flop circuit 309 of the data retention circuit 300, and the flip-flop circuit 309 is driven by the voltage VDDZ.

In the present embodiment, the switch circuit 590A, which is connected to the flip-flop circuit 309, includes the p-type transistor 591 and the resistor element 595 which is connected in parallel to the current path of the p-type transistor 591. At the time of the normal mode, the power supply voltage VDD is supplied to the p-type transistor 591, and is hardly supplied to the resistor element 595. Thus, at the time of the normal mode, the switch circuit 590A outputs the voltage VDDZ (nVDDZ), which is substantially equal in magnitude to the power supply voltage VDD, to the flip-flop circuit 309.

At the time of the normal mode of the LSI 1, the logic circuit 200 executes a predetermined process (signal process/calculation process). At the time of the normal mode, the master latch ML of the flip-flop circuit 309 stores, for example, various information used in the normal operation of the LSI 1 (e.g. the setting information of the logic circuit 200), the processing result of the logic circuit 200, or the input signal from the outside.

When a command from the outside has been supplied after the normal mode, or when no input signal from the outside has been supplied during a time period, the control circuit 400 changes the operation mode of the LSI 1 from the normal mode to the sleep mode at a certain timing.

Before the operation mode of the LSI 1 changes to the sleep mode, the data (setting information) of the logic circuit 200 or master latch ML is transferred to the balloon latch BL. For example, during the normal mode, the data of the logic circuit 200 or master latch ML is being transferred to the balloon latch BL.

After the balloon latch BL has taken in the setting information, the control circuit 400 supplies the control signal pIN0 of H level to each switch circuit 500, 590A. By the control signal pIN0 of H level, the p-type transistors 501 and 591 in the switch circuits 500 and 590A are turned off, respectively.

At the time of the sleep mode, the p-type transistor 501 in the switch circuit 500 is turned off by the control signal pIN0 of H level, and the logic circuit 200 is electrically isolated from the power line 900 by the p-type transistor 501 which is in the OFF state.

Thereby, the output voltage VDDV of the switch circuit 500 becomes 0 V, and the supply of power to the logic circuit 200 is shut off.

In this manner, at the time of the sleep mode, the logic circuit 200 enters a non-driven state. The various data/information in the logic circuit 200 is lost.

For example, at the time of the sleep mode, the supply of a voltage to the master latch ML in the flip-flop circuit 309 is shut off, and the master latch ML enters the non-driven state. Therefore, at the time of the sleep mode, the stored data in the master latch ML is lost.

The p-type transistor 591 of the switch circuit 590A is turned off by the control signal pIN0 of H level, which is common to the switch circuit 500. The supply path (connection path, voltage/current path) between the power line 900 and flip-flop circuit 309 via the p-type transistor 591, which is one of the p-type transistor 591 and resistor 595 that are connected in parallel to each other, is shut off by the p-type transistor 591 which is in the OFF state.

At the time of the sleep mode, the flip-flop circuit 309 and the balloon latch BL in the flip-flop circuit 309 are connected to the power line 900 by using the resistor element 595 as the connection path.

The power supply voltage (input voltage) VDD is applied to the resistor element 595 in the switch circuit 590A. A voltage drop of the input voltage VDD occurs due to the resistor element 595, and the output voltage sVDDZ of the switch circuit 590A at the time of the sleep mode becomes less than the input voltage VDD. The drop amount of the voltage due to the resistor element 595 corresponds to the magnitude of the resistance value R of the resistor element 595. The output voltage sVDDZ (=VDD−R×Ir) is equal to or greater than the threshold voltage Vth of the balloon latch BL.

The output voltage sVDDZ with the magnitude of “VDD−R×Ir” is supplied to the balloon latch BL.

The balloon latch BL is driven by the output voltage sVDDZ (=VDD−R×Ir) which is supplied via the resistor element 595, and the balloon latch BL maintains the data retention state at the time of the sleep mode by the voltage which is less than the power supply voltage VDD.

Thereby, in the present embodiment, compared to the case in which the balloon latch BL is driven by the power supply voltage VDD, the occurrence of leak current of the balloon latch BL at the time of the sleep mode is suppressed. Therefore, in the present embodiment, the balloon latch BL stores, with lower power consumption, the setting information for driving the LSI 1 and logic circuit 200.

By the supply of the command and signal from the outside, the LSI 1 is caused to transition from the sleep mode to the normal mode.

The control circuit 400 turns on the p-type transistors 501 and 591 by the control signal pIN0 of L level, and resumes the supply of power to the logic circuit 200 and master latch ML and the like. At this time, since the balloon latch BL is connected to the power line 900 via the p-type transistor 591 which is in the ON state, the magnitude of the voltage VDDZ, which is supplied to the balloon latch BL, changes to the power supply voltage VDD.

As described above, during the sleep mode, the setting information of the LSI 1 and logic circuit 200 is stored in the balloon latch BL. At the time of the restoration operation to the normal mode, the setting information of the internal circuit 10 and logic circuit 200 is re-set by using the data stored in the balloon latch BL.

After the re-setting of the logic circuit 200 is completed, the LSI 1 is driven in the normal mode.

In this manner, the LSI 1 of this embodiment can re-set the setting information of the internal circuit 10 and logic circuit 200 by using the data stored in the balloon latch BL. Thereby, in the LSI 1 of this embodiment, the speed of the restoration operation from the sleep mode to the normal mode can be increased, compared to the case in which the re-setting of the circuits 10 and 200 is executed by using setting information from the outside.

As has been described above, according to the semiconductor integrated circuit of the first embodiment, an increase in operation speed can be realized, while an increase in power consumption (standby power) is suppressed.

### <B-3> Modification

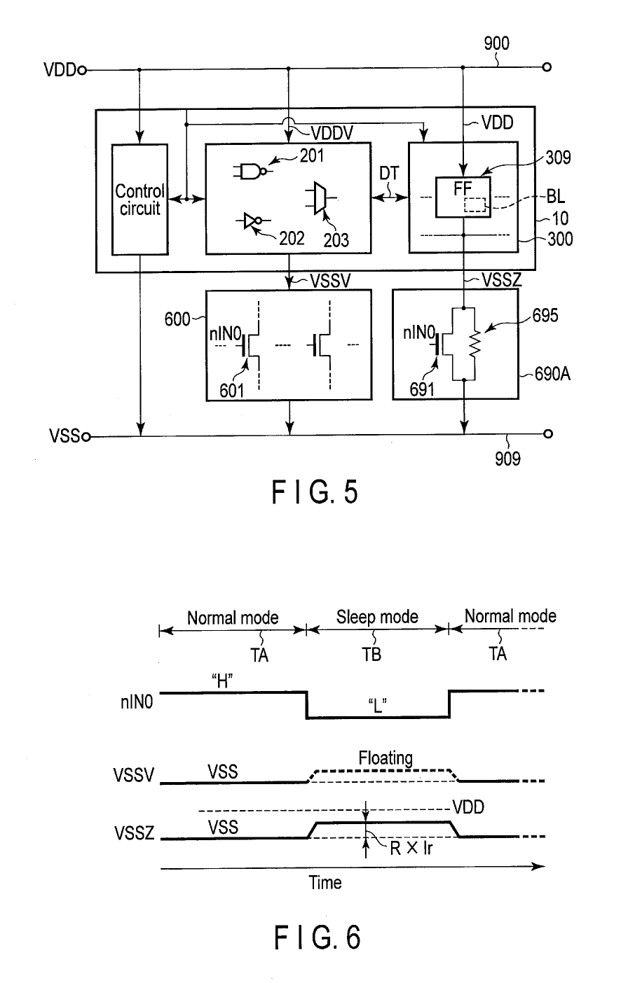

Referring to FIG. 5 and FIG. 6, a modification of the semiconductor integrated circuit of the first embodiment is described. An overlapping description of the circuit configuration and operation, which have already been described with reference to FIG. 2 and FIG. 4, is omitted.

FIG. 5 is a view illustrating a circuit configuration of an LSI 1 of this modification.

As illustrated in FIG. 5, switch circuits 600 and 690A, which control the supply of voltages to the internal circuit 10, may be provided between the ground line 909 and internal circuit 10.

The switch circuit 600 is provided between the logic circuit 200 and ground line 909. The switch circuit 600 includes an n-channel field effect transistor (hereinafter referred to as “n-type transistor”) 601 functioning as a switch element (power switch).

One end (one of a source and a drain) of a current path of the n-type transistor 601 is connected to the logic circuit 200, and the other end (the other of the source and drain) of the current path of the n-type transistor 601 is connected to the ground line 909.

The switch circuit 690A is provided between the flip-flop circuit 309 and ground line 909. The switch circuit 690A includes an n-type transistor 691 and a resistor element 695. The resistor element 695 is connected in parallel to a current path of the n-type transistor 691.

One end of the current path of the n-type transistor 691 is connected to the flip-flop circuit 309, and the other end of the current path of the n-type transistor 691 is connected to the ground line 909.

One end of the resistor element 695 is connected to the flip-flop circuit 309, and the other end of the resistor element 695 is connected to the ground line 909.

The switch circuit 690A is connected to, for example, the balloon latch BL in the flip-flop circuit 309.

In the switch circuit 600, 690A, the ON/OFF of the n-type transistor 601, 691 is controlled by a control signal nIN0 from the control circuit 400.

FIG. 6 is a timing chart of respective signals and respective voltages for describing an operation example of the semiconductor integrated circuit of the present modification.

As illustrated in FIG. 6, in the normal mode of the LSI 1, the n-type transistors 601 and 691 are turned on by a control signal nIN0 of H level. The logic circuit 200 and flip-flop circuit 309 (balloon latch BL) are connected to the ground line 909 via the n-type transistors 601 and 691, respectively.

In this case, when an H-level gate voltage is being applied, if the driving force of the n-type transistor 691 is sufficiently large, the voltage/current from the flip-flop circuit 309 is mainly supplied to the n-type transistor 691 which is in the ON state, and is hardly supplied to the resistor element 695.

At the time of the sleep mode of the LSI 1, the n-type transistors 601 and 691 are turned off by a control signal nIN0 of L level.

The logic circuit 200 is electrically isolated from the ground line 909 by the n-type transistor 601 which is in the OFF state. Thereby, the supply of power to the logic circuit 200 is shut off. At the time of the sleep mode, a potential difference VSSV between the logic circuit 200 and switch circuit 600 is 0 V, or is in a floating state.

In the switch circuit 690A which is associated with the flip-flop circuit 309/balloon latch BL, the n-type transistor 691 is turned off by the control signal nIN0.

In the present embodiment, at the time of the sleep mode, the flip-flop circuit 309 is connected to the ground line 909 via the resistor element 695. Therefore, the resistor element 695 serves as the supply path (voltage path/current path) between the flip-flop circuit 309 and ground line 909.

At the time of the sleep mode, the flip-flop circuit 309 is connected to the power line 900, and the power supply voltage VDD is applied to the flip-flop circuit 309.

Due to the resistor element 695, a potential VSSZ between the flip-flop circuit 309 and switch circuit 690A floats (rises) to a magnitude of about R×Ir.

As a result, the potential difference (VDD−R×Ir) between the power line 900 and switch circuit 690A becomes less than the potential difference between the power supply voltage VDD and ground voltage VSS. The potential difference (VDD−R×Ir), which is applied to the balloon latch BL (flip-flop circuit 309) at the time of the sleep mode, has a magnitude which is equal to or greater than the threshold voltage Vth of the balloon latch BL, with the resistance value R of the resistor element 695 being controlled. Therefore, at the time of the sleep mode of the LSI 1, the balloon latch BL continues the retention of data.

In this manner, at the time of the sleep mode, the flip-flop circuit 309/balloon latch BL is driven by a voltage which is less than the potential difference between the power supply voltage VDD and ground voltage VSS. Therefore, compared to the case in which the balloon latch BL is directly connected to the ground line 909, the leak current of the flip-flop circuit 309/balloon latch BL is reduced, and the flip-flop circuit 309/balloon latch BL retains the setting information of the LSI 1 and logic circuit 200 with lower power consumption.

When a transition is made from the sleep mode to the normal mode, the control signal nIN0 is set from L level to H level, and the supply of power to the respective circuits is resumed. With the data of the balloon latch BL being used, the setting information of the logic circuit 200 is re-set.

By the re-setting of the setting information in the logic circuit 200, the logic circuit 200 executes a predetermined process.

In this manner, in the LSI 1 of the present modification, at the time of the sleep mode, the occurrence of excessive leak current/power consumption in the balloon latch BL (flip-flop circuit 309) can be suppressed. In addition, at the time of the transition from the sleep mode to the normal mode, the speed of the restoration operation of the internal circuit 10 and logic circuit 200 can be increased.

Therefore, also in the case where the respective switch circuits 600 and 690A are provided between the respective circuits 200 and 300 and the ground line 909, as in the semiconductor integrated circuit of this modification, an increase in operation speed of the semiconductor integrated circuit can be realized, while the power consumption of the semiconductor integrated circuit can be reduced.

### (C) Second Embodiment

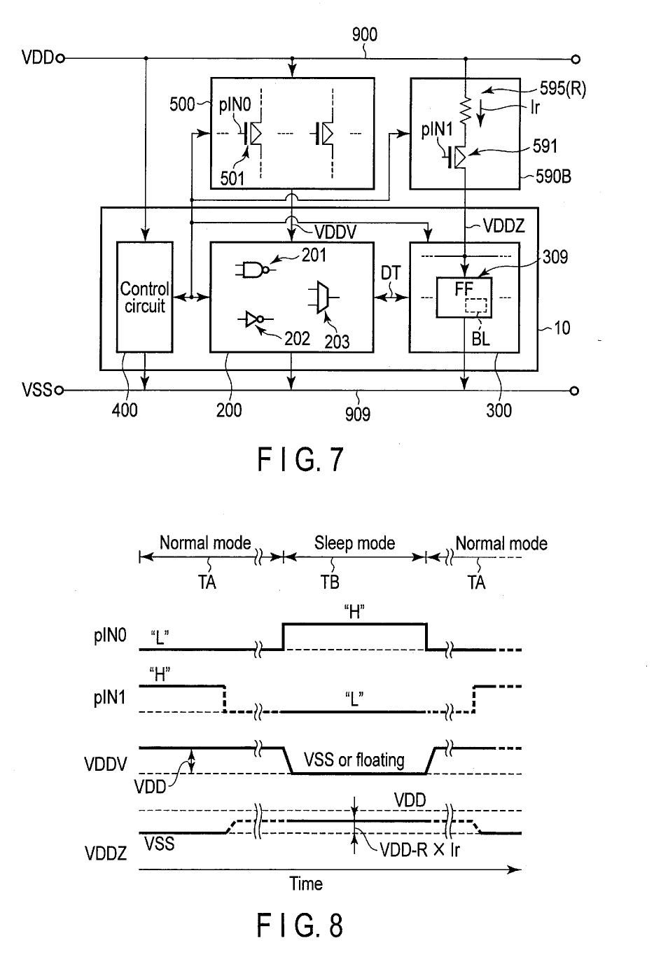

Referring to FIG. 7 and FIG. 8, a semiconductor integrated circuit of a second embodiment is described.

In the second embodiment, different points between this embodiment and the first embodiment will be mainly described.

### <C-1> Configuration Example

The semiconductor integrated circuit of the second embodiment is described with reference to FIG. 7.

In an LSI 1 of this embodiment, the internal configuration of the switch circuit, which is associated with the flip-flop circuit 309 (balloon latch BL), is different from the internal configuration of the switch circuit in the first embodiment.

In a switch circuit 590B of this embodiment, a resistor element 595 is connected in series to the current path (source/drain) of a transistor 591.

As in the switch circuit 590B illustrated in FIG. 7, one end of the resistor element 595 is connected to the power line 900, the other end of the resistor element 595 is connected to one end of the current path of the p-type transistor 591, and the other end of the current path of the p-type transistor 591 is connected to the flip-flop circuit 309 (the power supply terminal of the balloon latch BL).

The control circuit 400 supplies a control signal pIN0 to the switch circuit 500, and supplies a control signal pIN1 to the switch circuit 590B. The control signal pIN0 is independent from the control signal pIN1.

In the present embodiment, the balloon latch BL is not driven during a certain period in the normal mode.

Therefore, a part and the balloon latch BL in the flip-flop circuit 309 can be set in the OFF state (inactive state) at the time of the normal mode, and the supply of the voltage VDD to the balloon latch BL can be shut off. In other words, when the logic circuit 200 is driven, the balloon latch BL is in the standby state.

As a result, in the LSI 1 of this embodiment, the power consumption of the flip-flop circuit 309/balloon latch BL at the time of the normal mode can be reduced and the power consumption of the LSI 1 can be reduced.

At the time of the sleep mode, the flip-flop circuit 309/balloon latch BL is driven by using the voltage sVDDZ (VDD−R×Ir) which has been decreased by a voltage drop by the resistor element 595. Therefore, even if the balloon latch BL is in the non-driven state at the time of the normal mode, the data retention state of the balloon latch in the sleep mode is continued. As a result, in the LSI 1 of this embodiment, the speed of the transition from the sleep mode to normal mode of the LSI 1 can be increased.

In addition, even if the balloon latch BL is driven at the time of the sleep mode, the flip-flop circuit 309/balloon latch BL is driven by the voltage which is less than the power supply voltage VDD. Thus, in the LSI 1 of this embodiment, the leak current of the balloon latch BL can be reduced, and it is possible to suppress an excessive increase of power consumption of the LSI 1 due to the driving of the balloon latch BL at the time of the sleep mode.

In the meantime, substantially similarly with the example illustrated in FIG. 5, the switch circuit in the present embodiment may be provided between the flip-flop circuit (balloon latch) and the ground line. Between the balloon latch and the ground line, the resistor element is connected in series to the current path of the transistor. In this case, too, the leak current and power consumption of the balloon latch at the time of the normal mode can be reduced.

### <C-2> Operation Example

Referring to FIG. 8, an operation example of the semiconductor integrated circuit of the second embodiment is described.

FIG. 8 is a timing chart of respective signals and respective voltages for describing an operation example of the semiconductor integrated circuit of the second embodiment.

As illustrated in FIG. 8, in the normal mode of the LSI 1, the control circuit 400 supplies a control signal pIN0 of L level to the switch circuit 500, and supplies a control signal pIN1 of H level to the switch circuit 590B.

By the control signal pIN0 of L level, the p-type transistor 501 is turned on. The voltage VDDV (=VDD) is applied to the logic circuit 200 via the p-type transistor 501 which is in the ON state.

By the control signal pIN1 of H level, the p-type transistor 591 is turned off. The power line 900 is electrically isolated from the flip-flop circuit 309 (balloon latch BL) by the p-type transistor 591 which is in the OFF state. Thereby, the supply of the voltage VDDZ to the flip-flop circuit 309 (balloon latch BL) is shut off.

As a result, the power consumption of the balloon latch BL at the time of the normal mode is reduced.

When a transition is made from the normal mode to the sleep mode, the control circuit 400 supplies the control signal pIN1 of L level to the switch circuit 590B, in the state in which the control signal pIN0 of L level is being supplied to the switch circuit 500.

By the control signal pIN1 of L level, the p-type transistor 591 is turned on.

Thereby, the voltage from the power line 900 is applied to the balloon latch BL of the flip-flop circuit 309 via the resistor element 595 and p-type transistor 591 which are connected in series.

The power supply voltage VDD is lowered by the resistor element 595 in the switch circuit 590B. Therefore, the balloon latch BL is driven by the internal voltage VDDZ (=VDD−R×Ir>Vth) which is less than the power supply voltage VDD.

The balloon latch BL, which is driven by the internal voltage sVDDZ, takes in the data of the logic circuit 200 and master latch ML.

After the setting information of the logic circuit 200 is stored in the balloon latch BL, the p-type transistor 501 is turned off by the control signal pIN0 of H level, and the supply of power to the logic circuit 200 is shut off.

At the time of the sleep mode, the balloon latch BL is driven by the internal voltage sVDDZ, and continues to retain the data.

When a transition is made from the sleep mode to the normal mode, the control circuit 400 sets the signal level of the control signal pIN0 to L level from H level, and the supply of power to the logic circuit 200 and master latch ML is resumed.

The data of the balloon latch BL is transferred to the logic circuit 200 and master latch ML, which are in the driven state.

After the re-setting of the setting information, the control circuit 400 sets the signal level of the control signal pIN1 to H level from L level, and the switch circuit 590B shuts off the supply of power to the balloon latch BL. Thereby, after the restoration operation of the logic circuit 200, the balloon latch BL enters the non-driven state.

In this manner, in the LSI 1 of the second embodiment, like the first embodiment, the power consumption occurring in the balloon latch BL at the time of the sleep mode can be reduced, and the speed of the restoration operation to the normal mode can be increased.

Furthermore, in the LSI 1 of the second embodiment, at the time of the normal mode, the supply of power to the balloon latch BL, which does not need to be driven, can be shut off. Thereby, in the LSI 1 of this embodiment, the power consumption of the balloon latch BL at the time of the normal mode can be reduced.

Therefore, according to the semiconductor integrated circuit of the second embodiment, the power consumption of the semiconductor integrated circuit can be reduced, and the speed of the operation of the semiconductor integrated circuit can be increased.

### (D) Third Embodiment

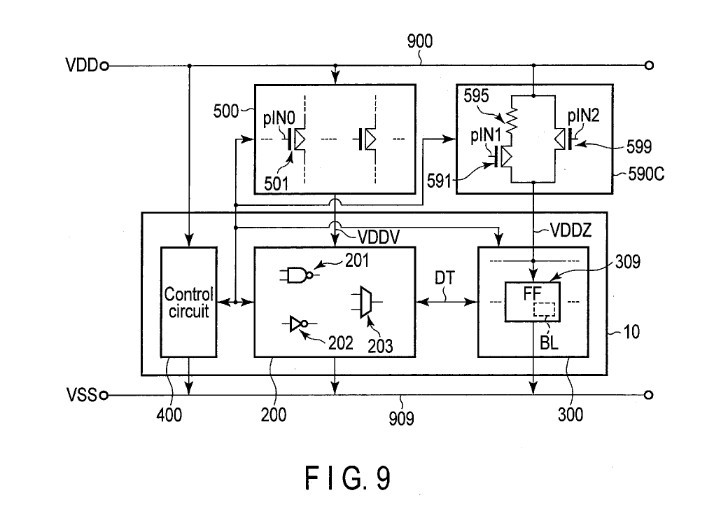

Referring to FIG. 9 to FIG. 12, a semiconductor integrated circuit of a third embodiment is described.

In the third embodiment, different points between this embodiment and the preceding embodiments will be mainly described.

### <D-1> Configuration Example

A configuration example of the semiconductor integrated circuit of the third embodiment is described with reference to FIG. 9.

An LSI 1 of the third embodiment includes a transition mode as an operation mode between the normal mode and the sleep mode.

In the LSI 1 of this embodiment, during the transition mode, the data/setting information in the logic circuit 200 is transferred between the balloon latch BL and logic circuit 200, or between the balloon latch BL and master latch ML.

In the LSI 1 of the present embodiment, the internal configuration of a switch circuit 590C, which is associated with the balloon latch BL, differs from the internal configuration of each of the switch circuits in the first and second embodiments, so as to adapt to the three operation modes.

In the switch circuit 590C of this embodiment, a resistor element 595 is connected in series to the current path of a p-type transistor 591.

In the switch circuit 590C, a p-type transistor 599 is connected in parallel to a supply path including the transistor 591 and resistor element 595 which are connected in series.

One end of the current path of the p-type transistor 599 is connected to one end of the resistor element 595 (an input node of the switch circuit 590C), and the other end of the current path of the p-type transistor 599 is connected to the other end of the p-type transistor 591 (an output node of the switch circuit 590C).

In this manner, the switch circuit 590C in the LSI 1 of this embodiment includes, within the circuit 590C, two supply paths (voltage/current paths, connection paths).

At the time of the normal mode, the two p-type transistors 591 and 599 in the switch circuit 590C are turned off. At the time of the normal mode, the switch circuit 590C electrically isolates the balloon latch BL in the flip-flop circuit 309 from the power line 900. Thereby, at the time of the normal mode, the supply of a voltage to the balloon latch BL is shut off by the switch circuit 590C.

At the time of the transition mode, the p-type transistor 599 is turned on. At the time of the transition mode, the power supply voltage VDD is output, as an internal voltage VDDZ, to the flip-flop circuit 309 via the p-type transistor 599 which is in the ON state, and is applied to the balloon latch BL.

At the time of the sleep mode, among the two p-type transistors 591 and 599 in the switch circuit, the p-type transistor 591 that is connected in series to the resistor element 595 is turned on by a control signal pIN1, and the p-type transistor 599 that is connected in parallel to the resistor element 595 is turned off by a control signal pIN2. The balloon latch BL is connected to the power line 900 via a supply path which is composed of the p-type transistor 591 and resistor element 595.

Thereby, at the time of the sleep mode, a voltage VDDZ, which is less than the power supply voltage, is applied to the balloon latch BL, and the balloon latch BL retains data.

The control circuit 400 supplies a control signal pIN0, pIN1 and pIN2, which are independent from each other, to the p-type transistors 501, 591 and 599 functioning as power switch elements. The ON/OFF of the p-type transistor 501, 591, 599 is independently controlled by the control signal pIN0, pIN1, pIN2.

Incidentally, in the present embodiment, at the time of the transition mode, the p-type transistor 591 may be turned off or may be turned on.

At the time of the transition mode, the power supply voltage VDD of the power line 900 is applied, with no voltage drop due to the resistor element 595, to the balloon latch BL via the p-type transistor 599 which is in the ON state.

In this manner, in the LSI 1 of this embodiment, at the time of the transition mode, the power supply voltage VDD is supplied, as the output voltage VDDZ of the switch circuit 590C, to the balloon latch BL of the flip-flop circuit 309.

Therefore, in the present embodiment, compared to the case where the balloon latch, which is driven by a voltage less than the power supply voltage VDD, executes data transfer, the balloon latch BL can execute the retention operation of data (take-in of data) and the output operation of data with a high driving force (high data transfer ability/high operation property).

As a result, in the LSI 1 of this embodiment, at the time of the transition mode, the time that is needed for data transfer between the logic circuit 200 and balloon latch BL can be shorted, and the operation speed of the logic circuit 200 can be increased.

### <D-2> Operation Example

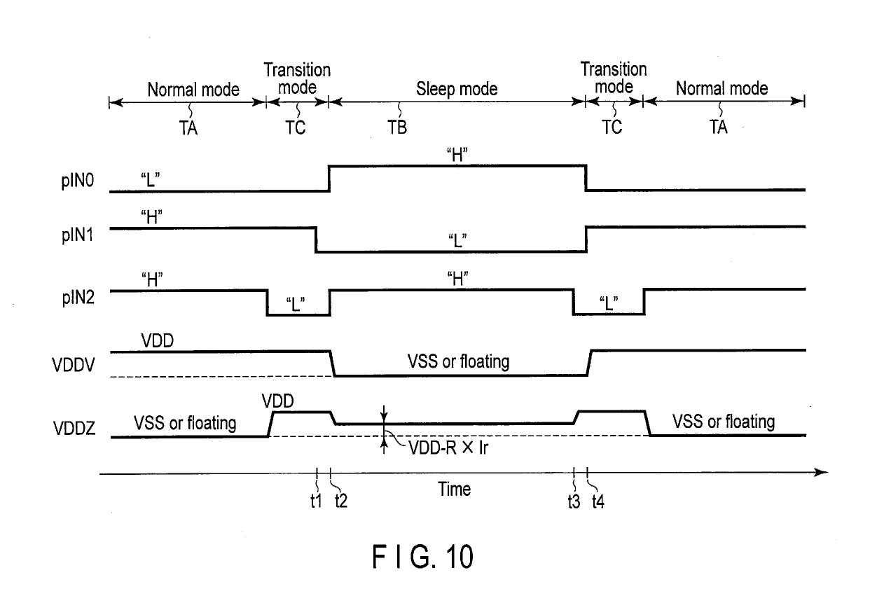

Referring to FIG. 10, an operation example of the semiconductor integrated circuit of the third embodiment is described.

FIG. 10 is a timing chart of respective signals and respective voltages for describing an operation example of the semiconductor integrated circuit of the third embodiment.

As illustrated in FIG. 10, at the time of the normal mode, the p-type transistor 501 of the switch circuit 500 is turned on, and the internal voltage VDDV is applied to the logic circuit 200.

In the switch circuit 590C which is associated with the balloon latch BL of the flip-flop circuit 309, the two control signals pIN1 and pIN2 are set at H level, and both of the two p-type transistors 591 and 599 are turned off. Thereby, the balloon latch BL is electrically isolated from the power line 900.

As a result, the power consumption of the balloon latch BL at the period TA of the normal mode is reduced.

At the time of the end of the normal mode, prior to the start of the sleep mode, the internal circuit 10 of the LSI 1 is driven in the transition mode.

At the time (the period TC of the transition mode) of the transition mode, like the normal mode, the p-type transistor 501 is turned on, and the internal voltage VDDV (=VDD) is applied to the logic circuit 200.

As regards the switch circuit 590C on the balloon latch BL (flip-flop circuit 309) side, at the time of the transition mode, the p-type transistor 599 is turned on by the control signal pIN2 of L level.

Thereby, the balloon latch BL is connected to the power line 900 via the p-type transistor 599 which is in the ON state. In this manner, at the time of the transition mode, the flip-flop circuit 309/balloon latch BL is connected to the power line 900, not via the supply path including the resistor element 595.

Therefore, the balloon latch BL is driven by the voltage VDDZ which is substantially equal in magnitude to the power supply voltage VDD. The balloon latch BL takes in the data from the logic circuit 200 with a high driving force (data transfer ability/operation property) corresponding to the power supply voltage VDD. As a result, in the LSI 1 of this embodiment, compared to the case where the balloon latch is driven by a voltage less than the power supply voltage VDD, the transition period TC from the normal mode to the sleep mode can be shortened, and the data transfer between the logic circuit 200 and balloon latch BL can be executed at high speed and high efficiency.

After the data transfer from the logic circuit 200 to the balloon latch BL is completed, the operation mode of the LSI 1 is changed from the transition mode to the sleep mode.

At the time of the sleep mode, the p-type transistor 501 is turned off by the control signal pIN0 of H level, and the supply of power to the logic circuit 200 is shut off.

The control circuit 400 supplies the control signal pIN1 of L level to the p-type transistor 591, and supplies the control signal pIN2 of H level to the p-type transistor 599. Thereby, among the two p-type transistors 591 and 599 in the switch circuit 590C, the p-type transistor 591 is turned on, and the p-type transistor 599 is turned off.

The balloon latch BL is electrically connected to the power line 900 via the p-type transistor 591 which is in the ON state, and the resistor element 595. The voltage VDDZ (=VDD−R×Ir), to which the power supply voltage VDD has been decreased by a voltage drop by the resistor element 595, is supplied to the balloon latch BL.

At the time of the sleep mode, the balloon latch BL, to which the voltage VDDZ is applied, maintains the data retention state.

In this case, during the period TC of the transition mode, it is preferable that the control signal pIN1 is caused to transition from H level to L level at a timing t1 before a timing (time) t2 at which the control signal pIN2 is caused to transition from L level to H level. For example, during the transition mode, the control signal pIN1 is set to L level from H level. Before the p-type transistor 599 of one supply path is turned off, the p-type transistor 591 of the other supply path is turned on.

In this manner, by the control of the transition timing of the control signals pIN1 and pIN2, the balloon latch BL is electrically connected to the power line 900, at a last stage of the transition mode (immediately before the sleep mode), via both of the two conduction paths of the switch circuit 590C.

Thereby, in the LSI 1 of this embodiment, when the supply path between the power line 900 and balloon latch BL is switched, it is possible to prevent the occurrence of a defect of timing of the switching, or a defect of power supply to the balloon latch BL due to an interconnect delay.

As a result, in the LSI 1 of this embodiment, loss of data in the latch BL can be prevented at a time of switching between the transition mode and the sleep mode.

In the meantime, instead of the control signal pIN1 being set at L level during the period TC of the transition mode in which the control signal pIN2 is set at L level, the control signal pIN1 may be set to L level from H level at the time t2 at which the sleep mode is started, and the control signal pIN2 may be set at L level during a period from the time t2 to a certain time after the time t2. The control signal pIN1 and control signal pIN2 may be set at L level at the same time.

In this manner, at the time of the sleep mode, the p-type transistor 501 associated with the logic circuit 200 is turned off, the p-type transistor 599 for the transition mode is turned off, and the p-type transistor 591 for the sleep mode is turned on.

During the transition period TC from the sleep mode to the normal mode, the LSI 1 is driven in the following manner.

When the operation mode is changed from the sleep mode to the transition mode, the control circuit 400 changes the level of the control signal pIN2 to L level from H level at a time t3 during the period TB of the sleep mode, in the state in which the control signal pIN1 is kept at L level.

At the time of switching from the sleep mode to the transition mode, since both of the two p-type transistors 591 and 599 are in the ON state, the balloon latch BL is electrically connected to the power line 900 via the two parallel supply paths.

At a time t4, the control circuit 400 sets the control signal pIN0 to L level from H level. Thereby, the logic circuit 200 is activated, and the LSI 1 is driven in the transition mode.

For example, the voltage VDD is applied to the master latch ML via the power switch (e.g. switch circuit 500) that is in the ON state.

At the time t4, the control circuit 400 changes the level of the control signal pIN1 from L level to H level, in the state in which the control signal pIN2 is kept at L level. The transistor 599 continues the ON state, and the p-type transistor 591 is turned off by the control signal pIN1 of H level.

The balloon latch BL is connected to the power line 900 via the p-type transistor 599 that is in the ON State, and the balloon latch BL is driven by the power supply voltage VDD.

The data in the balloon latch BL is transferred to the logic circuit 200 and master latch ML by the driving force (output property) of the latch, which corresponds to the power supply voltage VDD.

Based on the data from the balloon latch BL, the state of the logic circuit 200 is re-set, and the LSI 1 starts the operation in the normal mode.

At a certain timing, the p-type transistor 599 in the switch circuit 590C is turned off, and the supply of power to the balloon latch BL is shut off.

In the meantime, when the sleep mode transitions to the normal mode, in order to prevent loss of data of the balloon latch BL, the control signal pIN2 may be set at L level at the time t3 and the control signal pIN1 may be set at L level during a period until a certain time after the time t3.

As has been described above, in the LSI of this embodiment and the operation thereof, a lower power consumption and high speed of the LSI can be achieved, and the data transfer between the logic circuit and flip-flop circuit (balloon latch) at the time of the transition to the operation mode can be executed at high speed and high efficiency.

### <D-3> Modification

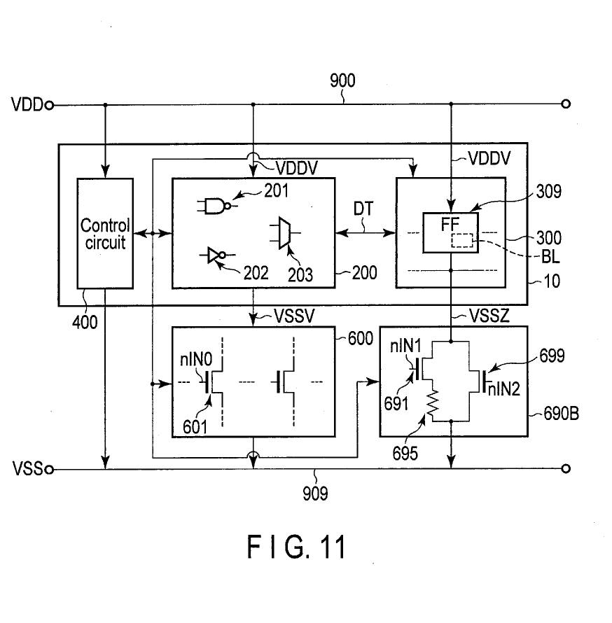

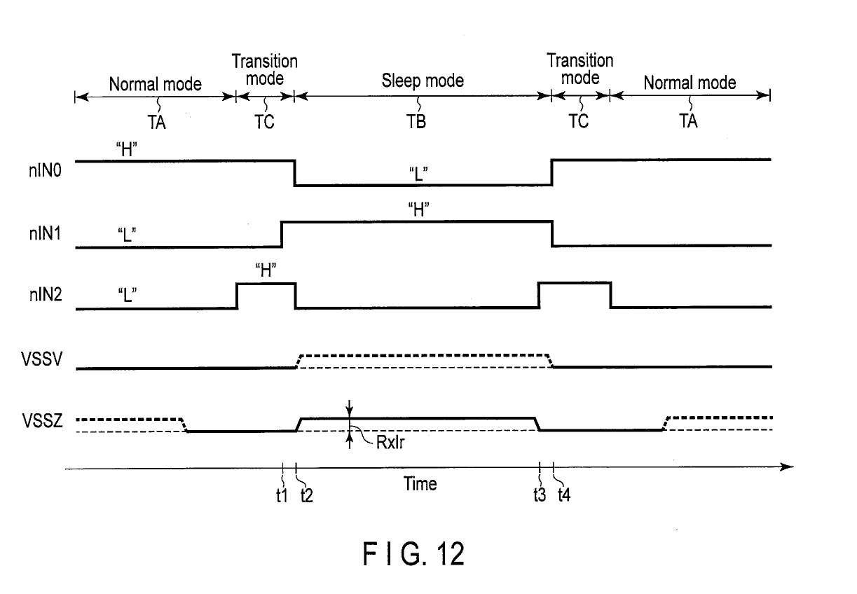

Referring to FIG. 11 and FIG. 12, a modification of the semiconductor integrated circuit of the third embodiment is described. In the present modification, an overlapping description of the circuit configuration and operation, which have already been described above, is omitted.

FIG. 11 is a view illustrating a circuit configuration of an LSI 1 of this modification.

As illustrated in FIG. 11, in order to adapt to the transition mode, a switch circuit 690B between the ground line 909 and the internal circuit 10 may include a supply path which is formed of a transistor 691 and a resistor element 695 that are connected in series, and a supply path formed of a transistor 699 alone.

The switch circuit 690B includes two n-type transistors 691 and 699. The current path of the n-type transistor 691 is connected in series to the resistor element 695. The current path of the n-type transistor 699 is connected in parallel to the supply path formed of the n-type transistor 691 and resistor element 695.

The control circuit 400 supplies a control signal nIN1 to the n-type transistor 691, and supplies a control signal nIN2 to the n-type transistor 699.

FIG. 12 is a timing chart of respective signals and respective voltages for describing an operation example of the LSI 1 of the present modification.

As illustrated in FIG. 12, at the time of the normal mode, the control circuit 400 sets the control signals nIN1 and nIN2 at L level. At the time of the normal mode, the balloon latch BL is electrically isolated from the ground line 909 by the n-type transistors 691 and 699 which are in the OFF state, and the supply of power to the balloon latch BL is substantially shut off.

During the transition period TC (transition mode) from the normal mode to the sleep mode, the control circuit 400 sets the control signal nIN2 to H level from L level. The balloon latch BL is connected to the ground line 909 via the n-type transistor 699 which is in the ON state, and the balloon latch BL is driven by the potential difference between the power line 900 and ground line 909. Data is transferred from the logic circuit 200 (master latch ML) to the balloon latch BL by the driving force (data transferring ability) of the balloon latch BL, which corresponds to the power supply voltage VDD.

At a time t1 during the period TC of the transition mode, the control circuit 400 changes the level of the control signal nIN1 from L level to H level, in the state in which the control signal nIN2 is kept at H level. The balloon latch BL is connected to the ground line 909 via the two supply paths in the switch circuit 690B.

After the control signal nIN1 is set at H level, the control circuit 400 sets, at a time t2, the control signal nIN0 at L level, and sets the control signal nIN2 at L level.

By the n-type transistor 601 being turned off, the supply of power to the logic circuit 200 is shut off, and the operation mode of the LSI 1 changes to the sleep mode. The n-type transistor 699 is turned off by the control signal nIN2 of L level.

The balloon latch BL is connected to the ground line 909 via the resistor element 695 and the n-type transistor 691 which is in the ON state.

Due to the resistor element 695, the potential of the supply path between the balloon latch BL and switch circuit 690B rises (floats). As a result, the balloon latch BL is driven by the potential difference (VDD−R×Ir) between the power supply voltage VDD and voltage “R×Ir”, and maintains the data retention state.

When the sleep mode transitions to the normal mode, the control circuit 400 changes, at a time t3, the level of the control signal nIN2 from L level to H level, in the state in which the control signal nIN1 is kept at H level. The balloon latch BL is connected to the ground line 909 via the two transistors 691 and 699 which are in the ON state.

After the n-type transistor 699 is turned on, the control circuit 400 sets, at a time t4, the control signal nIN0 at H level, and sets the control signal nIN1 at L level.

By the transistor 601 being turned on, the supply of power to the logic circuit 200 is resumed, and the logic circuit 200 is driven.

The balloon latch BL is connected to the ground line 909, not via the resistor element 695, but via the n-type transistor 699. In the transition mode, the balloon latch BL is driven by the power supply voltage VDD, and the balloon latch BL outputs the stored data to the logic circuit 200 (or master latch ML).

After the transfer of the data from the balloon latch BL is completed, the control circuit 400 sets the control signal nIN2 at L level, and the balloon latch BL is electrically isolated from the ground line 909.

As a result, the LSI 1 is driven in the normal mode. At the time of the normal mode, the supply of power to the balloon latch BL is shut off by the n-type transistors 691 and 699 which are in the OFF state.

As illustrated in FIG. 11 and FIG. 12, even in the case where the switch circuits 600 and 690B are provided between the internal circuit 10 and ground line 909, the LSI 1 of this modification can drive the balloon latch BL by the power supply voltage VDD at the time of the data transfer between the balloon latch BL and logic circuit 200.

As a result, in the LSI of this modification, like the LSI 1 illustrated in FIG. 9 and FIG. 10, the data transfer during the transition period between the normal mode and sleep mode can be executed at high efficiency and high speed.

### (E) Fourth Embodiment

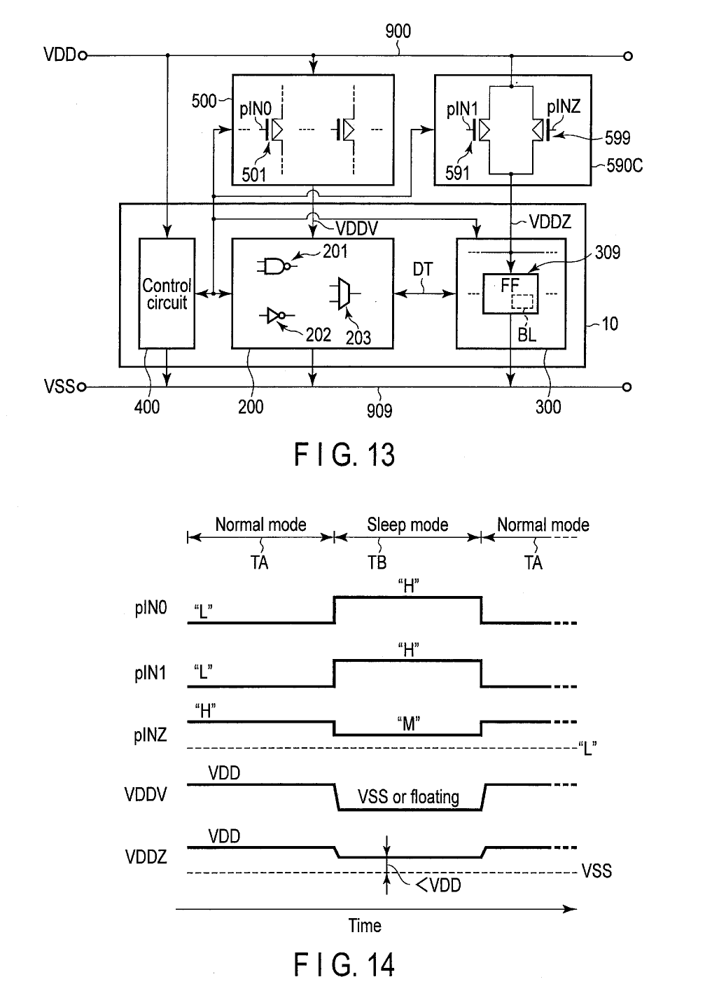

Referring to FIG. 13 to FIG. 18, a semiconductor integrated circuit of a fourth embodiment is described. In the fourth embodiment, different points between this embodiment and the preceding embodiments will be mainly described.

### <E-1> Configuration Example

A configuration example of the semiconductor integrated circuit of the fourth embodiment is described with reference to FIG. 13.

In the first to third embodiments, the switch circuit functioning as the power switch circuit includes the resistor element which is connected to its internal supply path.

A transistor may be used, in place of the resistor element, as a load in the supply path of the switch circuit, with the magnitude of the gate voltage of the transistor being controlled.

In an LSI 1 of this embodiment, the magnitude of the voltage/current, which is supplied to the flip-flop circuit and balloon latch, is controlled by the transistor (hereinafter referred to as “load transistor”) functioning as the load.

FIG. 13 is a view which schematically illustrates a circuit configuration of the LSI 1 of this embodiment.

As illustrated in FIG. 13, a switch circuit 590C includes two p-type transistors 591 and 599 which have current paths connected in parallel. One end of the current path of each transistor 591, 599 is connected to the power line 900, and the other end of the current path of each transistor 591, 599 is connected to the power supply terminal of the flip-flop circuit 309 (balloon latch BL).

In the present embodiment, among the two p-type transistors 591 and 599, one transistor 599 is called “load transistor”.

The control circuit 400 supplies mutually different control signals pIN1 and pINZ to the gates of the transistors 591 and 599, respectively.

The magnitude of the signal level of the control signal pIN1, pINZ serving as the gate voltage is controlled, and thereby the driving force of the transistor 591, 599 is controlled.

The load transistor 599 is turned on and off by the control signal pINZ. The load transistor 599 is driven by the driving force (magnitude α of the load) corresponding to the magnitude of the control signal (gate voltage) pINZ.

The control signal pINZ is a signal having a voltage value of a middle level (hereinafter designated as “M level”) between L level and H level. In this case, the voltage value (signal level) of M level is not limited to a value which is half the potential difference between the voltage value of L level and the voltage value of H level, but is a value which is properly set such that the output voltage VDDZ, which is output via the load transistor 599, has a desired value.

Incidentally, depending on the operation condition of the load transistor, there may be a case in which the control signal pINZ is set at L level, or there may be a case in which the control signal pINZ is set at H level. The output voltage VDDZ from the load transistor (p-type transistor) 599, to the gate of which the control signal pINZ of M level is applied, is less than the output voltage VDDZ of the transistor 599, to the gate of which the control signal pINZ of L level is applied.

In this manner, by controlling the magnitude of the signal level of the control signal pINZ, the transistor 599 is driven as the load transistor having substantially the same function as the resistor element.

When the load transistor 599 is substituted for the resistor element, as in the present embodiment, the output voltage VDDZ of the switch circuit can be made proper, by adjusting the magnitude of the control signal pINZ of the load transistor 599.

### <E-2> Operation Example

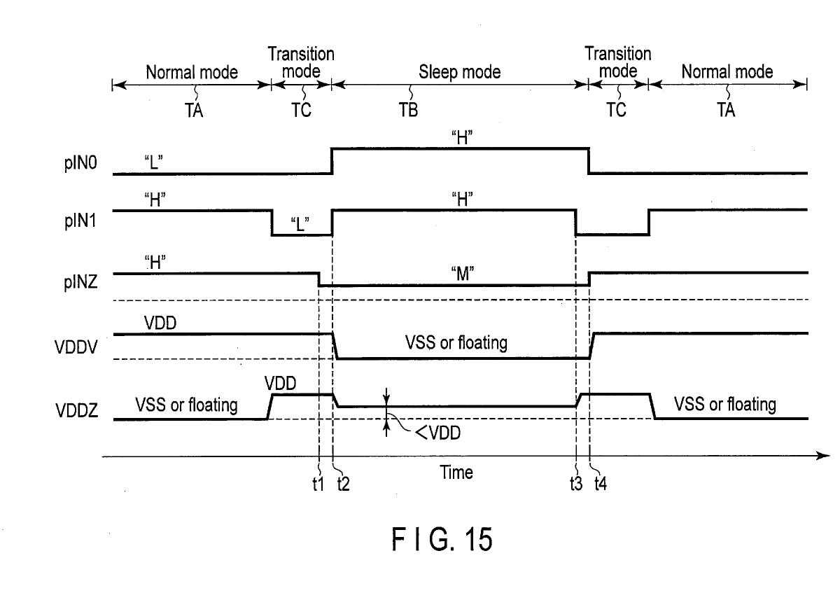

Referring to FIG. 14 and FIG. 15, an operation example of the LSI of the fourth embodiment is described.

FIG. 14 is a timing chart illustrating variations of respective signals for describing the operation example of the LSI 1 of FIG. 13. By the load transistor 599, the LSI 1 of FIG. 13 can be driven with substantially the same operation as in the first embodiment.

As illustrated in FIG. 14, at the time of the normal mode, the p-type transistor 501 is turned on by the control signal pIN0 of L level, and the logic circuit 200 is driven. The p-type transistor 591 is turned on by the control signal pIN1 of L level, and the flip-flop circuit 309 and balloon latch BL are driven by the power supply voltage VDD.

At the time of the normal mode, the control circuit 400 sets the control signal pINZ at H level, and the load transistor 599 is turned off.

At the time of the sleep mode, the transistor 501 is turned off by the control signal pIN0 of H level, and the supply of power to the logic circuit 200 is shut off. The p-type transistor 591 is turned off by the control signal pIN1 of H level.

At the time of the sleep mode, the control circuit 400 changes the signal level of the control signal pINZ from H level to M (middle) level, substantially at the same time as the timing at which the control signal pIN1 is set at H level. Thereby, the load transistor 599 supplies power (driving voltage) to the flip-flop circuit 309/balloon latch BL, with the driving force corresponding to the control signal (gate voltage) pINZ of M level. In accordance with the driving force of the load transistor 599 to which the control signal of M level has been supplied, a voltage, which is less than the power supply voltage VDD and is equal to or greater than the threshold value of the latch BL, is supplied to the balloon latch BL.

Incidentally, at a timing before the control signal pIN1 is set to H level from L level, the control signal pINZ may be set to M level from L level.

When the LSI 1 transitions from the sleep mode to the normal mode, the control circuit 400 changes the level of the control signal pINZ from M level to H level, substantially at the same time as the control circuit 400 changes the level of the control signal pIN0, pIN1 from H level to L level.

Thereby, the load transistor 599 is turned off, and power to the balloon latch BL is supplied by the p-type transistor 591 which is in the ON state.

In the meantime, at a timing after the control signal pIN1 is set to L level from H level (after the transistor 591 is turned on), the control signal pINZ may be set to H level from M level and the transistor 599 may be turned off.

In this manner, the LSI 1 including the load transistor 599 in the switch circuit 590C can be driven with substantially the same operation as the LSI 1 of the first embodiment.

The LSI 1 of FIG. 13 can be driven in the operation modes including the transition mode described in the third embodiment.

FIG. 15 is a timing chart of respective signals and respective voltages for describing an operation example of the LSI including a transition mode.

As illustrated in FIG. 15, during the normal mode, the control circuit 400 sets the transistor 591 in the OFF state, and sets the control signal pINZ at H level. Thereby, the load transistor 599 is set in the OFF state.

During the transition mode, the control circuit 400 changes the level of the control signal pINZ from H level to M level, before changing the level of the control signal pIN1 from L level to H level.

Thereafter, the control signals pIN0 and pIN1 are set at H level. Thereby, at the time of the sleep mode, the voltage VDDZ corresponding to the magnitude of the driving force (output property) of the load transistor 599, which is driven by the control signal pINZ of M level, is supplied to the balloon latch BL.

After the transistor 591 is turned on, at a certain time t4 during the transition period TC from the sleep mode to the normal mode, the control circuit 400 changes the level of the control signal pINZ from M level to H level, and turns off the load transistor 599.

In this manner, the LSI 1 including the load transistor 599 in the switch circuit 590C can be driven with substantially the same operation as the LSI 1 of the third embodiment.

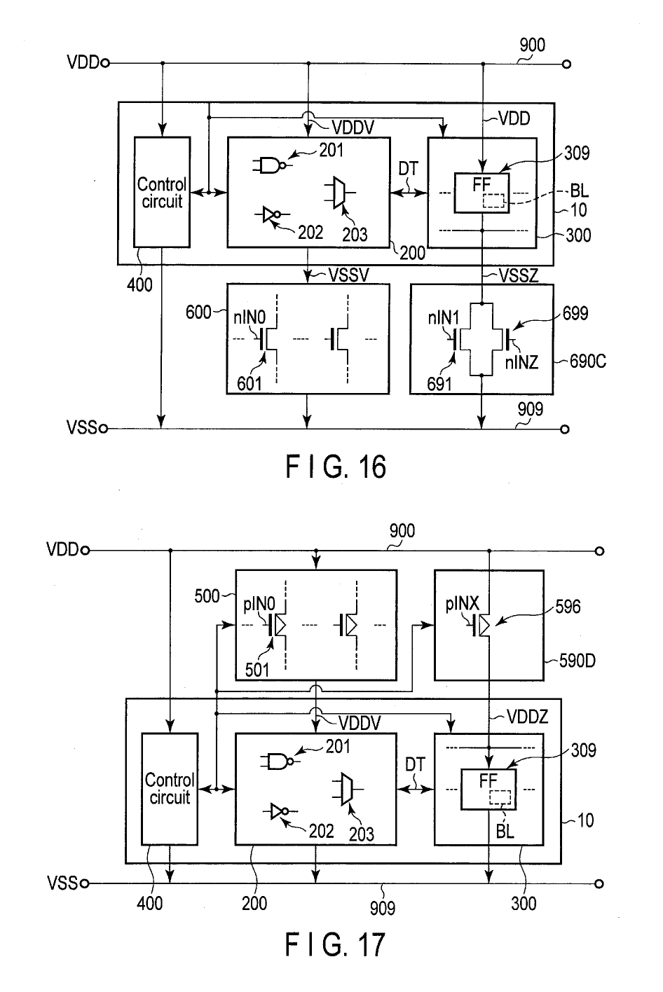

As illustrated in FIG. 16, a switch circuit 690C including an n-type transistor 691 and a load transistor 699, which are connected in parallel, may be provided on the ground line side.

In an LSI 1 of FIG. 16, at the time of the sleep mode, the signal level of a control signal nINZ of the load transistor 699 is set at M level.

Thereby, the LSI 1 of FIG. 16 can be driven with substantially the same operation as the LSIs described in the preceding embodiments.

### <E-3> Modification

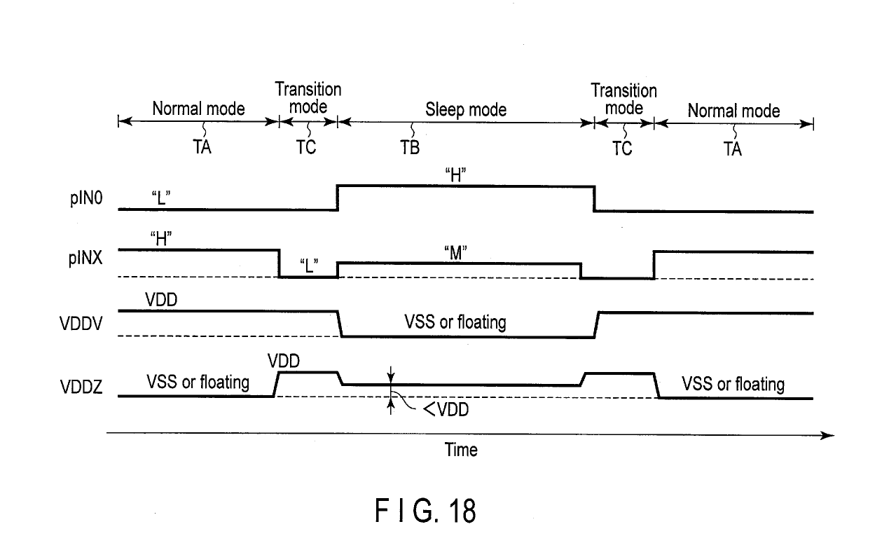

Referring to FIG. 17 and FIG. 18, a modification of the semiconductor integrated circuit of the fourth embodiment is described.

FIG. 17 is a view for describing the modification of the LSI 1 of the present embodiment.

As illustrated in FIG. 17, one transistor 596 may be provided in a switch circuit 590D. The magnitude of a control signal (gate voltage) to the transistor 596 is controlled such that the transistor 596 has both the functions of the power switch and load transistor.

When a control signal pINX of L level or H level has been supplied to the gate of transistor 596 as a gate voltage of the p-type transistor 596, the p-type transistor 596 functions as a power switch. Specifically, by the control signal pINX of H level, the transistor 596 that is in the OFF state shuts off the supply of power to the flip-flop circuit 309/balloon latch BL. By the control signal pINX of L level, the transistor 596 that is in the ON state transfers the power supply voltage VDD to the balloon latch BL.

When the control signal pINX of M level has been supplied from the control circuit 400 to the transistor 596 as the gate voltage of the p-type transistor 596, the transistor 596 functions as a load (resistor element).

The transistor 596, to which the control signal pINX of M level has been supplied, supplies a voltage/current to the balloon latch BL, with the driving force corresponding to the magnitude of the control signal pINX serving as the gate voltage.

FIG. 18 is a timing chart of respective signals and respective voltages for describing an operation example of the LSI 1 of FIG. 17.

The LSI 1 of FIG. 17 can be driven, for example, with substantially the same operation of the third embodiment.

As illustrated in FIG. 18, at the time of the normal mode of the LSI 1, the control signal pINX is set at H level. Thereby, the p-type transistor 596 is turned off, and the supply of power to the balloon latch BL is shut off.

At the time of the transition mode, the control signal pINX is set at L level by the control circuit 400, in the state in which the control signal pIN0 is kept at L level. Thereby, the power supply voltage VDD is supplied to the balloon latch BL as the internal voltage VDDZ. The balloon latch BL is driven by the driving force (data transferring ability) based on the voltage VDD, and acquires the data from the logic circuit 200 or master latch ML.

Thereafter, the control signal pIN0 is set at H level, and thereby the operation mode of the LSI 1 and logic circuit 200 transitions to the sleep mode. At the time of the sleep mode, the control signal pINX is set at M level, and the balloon latch BL is driven by the voltage VDDZ (<VDD) corresponding to the driving force (data transferring ability) of the transistor 596.

At the time of the restoration operation, the control signal pINX is set at L level, and the balloon latch BL is driven by the power supply voltage VDD.

In the meantime, in the LSI 1 of FIG. 18, at the time of the sleep mode, the signal level of the control signal pINX is set at M level, and thereby the LSI 1 can be driven with substantially the same operation as the LSIs of the first and second embodiments.

As has been described above, in the semiconductor integrated circuit of the present embodiment, also when the transistor is used as the load in place of the resistor element, a decrease in power consumption and an increase in speed of the semiconductor integrated circuit can be realized.

### (F) Applied Examples

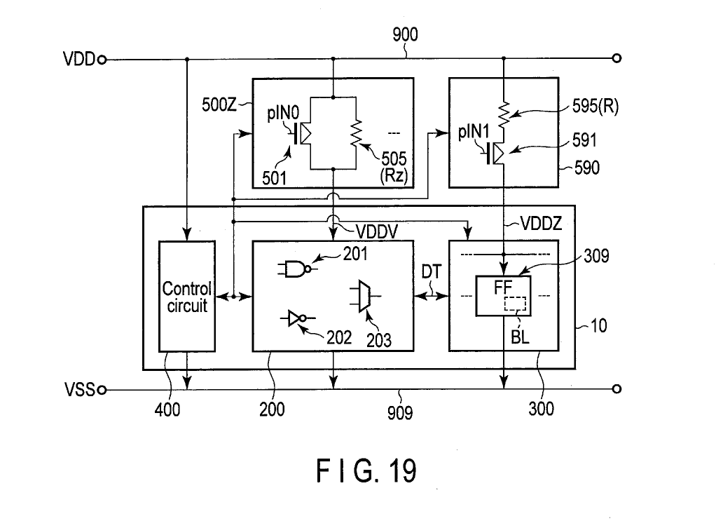

Referring to FIG. 19 to FIG. 21, modifications of the semiconductor integrated circuit of the embodiment are described.

FIG. 19 is a view for describing an example of modifications of the LSI of the embodiment.

As illustrated in FIG. 19, a switch circuit 500Z, which controls a connection between the logic circuit 200 and power line 900, may include a transistor 501 and a resistor element 505.

For example, in the switch circuit 500Z which is associated with the logic circuit 200 of the LSI 1 of FIG. 19, like the switch circuit in the first embodiment, the resistor element 505 is connected in parallel to the current path of the p-type transistor 501 functioning as the power switch.

At the time of the normal mode, the power supply voltage VDD is supplied to the logic circuit 200 as the driving voltage VDDV via the transistor 501 which is in the ON state.

At the time of the sleep mode, the p-type transistor 501 is turned off by the control circuit 400. The power supply voltage VDD on the power line 900 is supplied to the logic circuit 200 via the resistor element 505.

Thereby, at the time of the sleep mode, the voltage VDDV (VDD−Rz×Iz), which has been decreased by a voltage drop by the resistor element 505, is supplied to the logic circuit 200.

At the time of the sleep mode, the voltage, which is lower than the power supply voltage VDD, is being supplied to the logic circuit 200. Thereby, the speed of the restoration operation of the logic circuit 200 at the time of the transition from the sleep mode to the normal mode can be made higher than in the case in which the supply of power to the logic circuit 200 is completely shut off.

At the time of the sleep mode, unlike the flip-flop circuit 309/balloon latch BL, the logic circuit 200 may not maintain the operation state which satisfies a predetermined function. Specifically, at the time of the sleep mode, the power that is supplied to the logic circuit 200 may be less than the power supplied to the balloon latch BL.

Therefore, in order to increase the voltage drop on the logic circuit 200 side at the time of the sleep mode, the resistance value Rz of the resistor element 505 of the switch circuit 500 may be higher than the resistance value R of the resistor element 595 of the switch circuit 590.

Incidentally, in the LSI 1 of FIG. 19, a load transistor may be used in place of the resistor element 505.

In addition, the magnitude of the signal level of the control signal pIN0 of one p-type transistor 501 of the switch circuit 500 may be controlled, and thereby the p-type transistor 501 may be used as the power switch and may also be used as the load transistor. When the p-type transistor 501 is used as the load transistor, the p-type transistor 501 is driven by a control signal of a middle level between L level and H level.

When the switch circuit 500Z, which is associated with the logic circuit 200, includes the resistor element 505, the switch circuit 590, which is associated with the balloon latch BL, may have an internal configuration which is different from the internal configuration of the switch circuit 500Z, or may have the same internal configuration as the switch circuit 500Z.

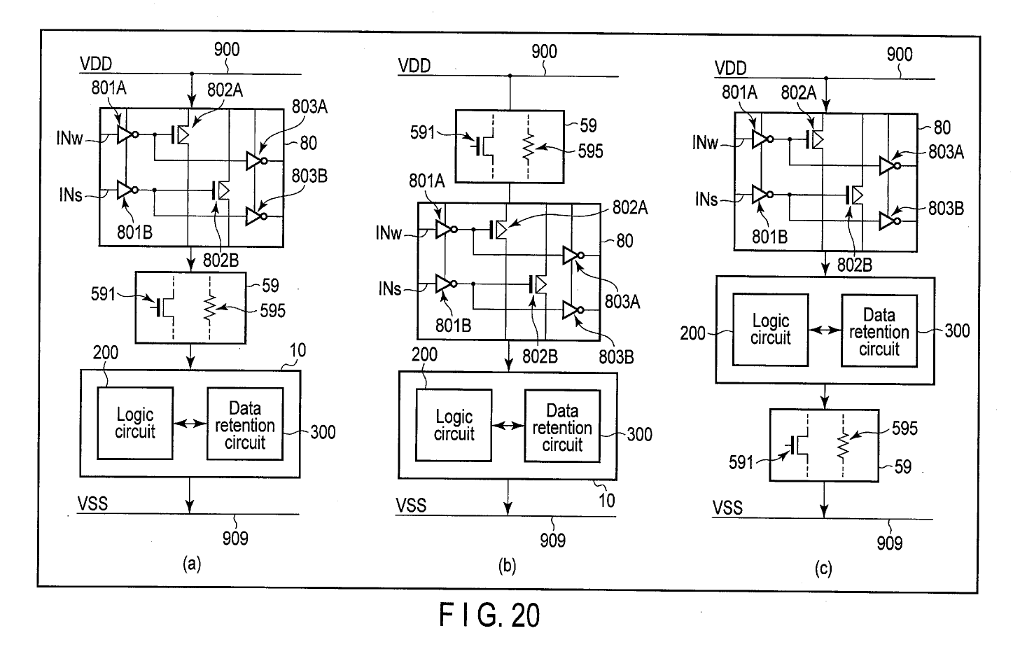

FIG. 20 is a view for describing an example of modifications of the LSI of the present embodiment.

As illustrated in part (a) of FIG. 20, the switch circuit 59 including the resistor element and switch (power switch), which has been described in the above embodiment, may be provided between the internal circuit 10 and a general power switch circuit 80.

The power switch 80 includes a switch (called “weak switch”) 802A for charging (or precharging) a wiring line (internal power line), and a switch (called “strong switch”) 802B for supplying an operation current/voltage to the circuit. Each switch 802A, 802B is a p-type transistor.

The ON/OFF of the p-type transistors 802A and 802B is controlled by control signals INw and INs, respectively.

The control signal INw is supplied to the gate of the p-type transistor 802A via an inverter 801A. An output signal of the inverter 801A is supplied to the transistor 802A, and also supplied to an input terminal of an inverter 803A. The inverter 803A outputs an inversion signal (a signal of the same phase as the control control signal INw) of the output signal of the inverter 801A to a rear-stage circuit (not shown) which is connected to an output terminal of the inverter 801.

The control signal INs is supplied to the gate of the p-type transistor 802B via an inverter 801B. An output signal of the inverter 801B is supplied to the transistor 802B, and also supplied to an input terminal of an inverter 803B. The inverter 803B outputs an inversion signal (a signal of the same phase as the control control signal INs) of the output signal of the inverter 801B to a rear-stage circuit (not shown) which is connected to an output terminal of the inverter 801.

The switch circuit 59 including the resistor element 595 of the embodiment is provided between the switch circuit 80 and the internal circuit 10.

The occurrence of leak current of a transistor causes an increase of power consumption of an LSI. With the development of microfabrication of a transistor, the channel length of the transistor becomes smaller and, as a result, the leak current of the transistor tends to become greater.

If the channel length of the transistor is increased in order to suppress the leak current, the output current of the transistor at a time of a normal mode decreases. Thus, in order to supply a desired driving voltage to the logic circuit at the time of the normal mode, the reduction in power consumption at the time of the normal mode may possibly become difficult.

It is thus desirable that the switch circuit be configured to be able to reduce leak current only at the time of the sleep mode.

In addition, when the size of the transistor is increased, the area in the chip, which is occupied by the power switch circuit, increases.

This being the case, it is possible that the reduction in power consumption and cost of the LSI becomes difficult, because of the characteristics and structure of the transistor functioning as the power switch.

In the present embodiment, the switch circuit 59 including the switch element 591 and resistor element 595 is used for the power gating of the LSI. Thereby, with a relatively small circuit scale, the leak current at the time of the sleep mode can be reduced without degradation in circuit characteristic or an increase in power consumption at the time of the normal mode.

In the meantime, as illustrated in part (b) of FIG. 20, the switch circuit 59 described in the embodiment may be provided between the power line 900 and the power switch circuit 80. In addition, as illustrated in part (c) of FIG. 20, the switch circuit 59 described in the embodiment may be provided between the internal circuit 10 and the ground line 909.

The LSIs illustrated in parts (b) and (c) of FIG. 20 can obtain substantially the same advantageous effects as the LSI of part (a) of FIG. 20.

As has been described above, as illustrated in FIG. 20, the LSI, in which the plural switch circuits 59 and 80 of the two-stage configuration are provided between the two power lines 900 and 909, can reduce the power consumption of the LSI, while suppressing an excessive increase in area of the switch circuit.

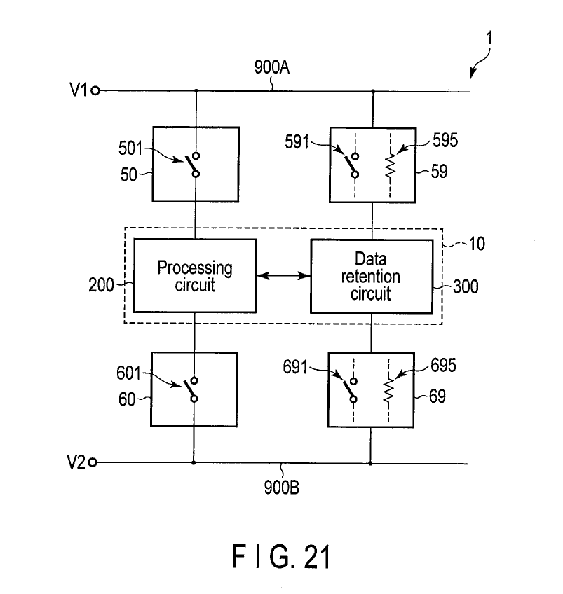

FIG. 21 is a view for describing an example of modifications of the LSI of the present embodiment. As shown by FIG. 21, power switch circuits 50 and 60 which are associated with the processing circuit 200 may be provided in both of the high potential line (power supply line) 900A side and the low potential line (grand line) 900B side.

In this case, power switch circuits 59 and 69 are provided to the data retention circuit 300 in both of the high potential line 900A side and the low potential line 900B side.

Power switch circuits 59 and 69, which are provided in the power supply line 900A side and the grand line 900B side, include resistors 595 and 695 in addition to the switch element (transistor) 591 and 691. Each of the resistor elements 595 and 695 is connected to each of the switch element 591 and 595 so as to have any one of configurations described by the first to fourth embodiments.

The LSIs illustrated in FIG. 21 can obtain substantially the same advantageous effects as the LSI described by the first to fourth embodiments.

### Others

The switch circuit included in the semiconductor integrated circuit of each of the above-described embodiments is applicable to, in addition to the logic circuit, an image sensor, a semiconductor memory or a wireless communication device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor integrated circuit device comprising:
a first power line to which a first voltage is applied;
a first circuit operating based on a first data;
a second circuit capable of retaining the first data;
a third circuit between the first power line and the first circuit and capable of shutting off a supply of the first voltage to the first circuit; and
a fourth circuit including a first resistor element, the first resistor element connected between the first power line and the second circuit,
wherein the fourth circuit supplies the first voltage to the second circuit via the first resistor element in a first period in which the third circuit shut off the supply of the first voltage to the first circuit.

2. The device according to claim 1, wherein
the fourth circuit includes a first switch element connected in parallel to the first resistor element between the first power line and the second circuit,
the fourth circuit connects the second circuit to the first power line by the first switch which is in an on-state, and
the fourth circuit electrically isolates the second circuit from the first power line by the first switch element which is in an off-state.

3. The device according to claim 2, wherein
in a second period when the third circuit supplies the first voltage to the first circuit,
the fourth circuit supplies the first voltage to the second circuit via the first switch element which is in an on-state.

4. The device according to claim 2, wherein
the third circuit includes a second switch between the first power line and the first circuit,
the first and second switch elements are turned on or off by a common control signal.

5. The device according to claim 1, wherein
the fourth circuit includes a first switch element connected in series to the first resistor element between the first power line and the second circuit,
the fourth circuit is capable of shut off a supply of the first voltage to the second circuit by the first switch element.

6. The device according to claim 5, wherein
in a second period when the third circuit supplies the first voltage to the first circuit,
the fourth circuit shuts off the supply of the first voltage to the second circuit.

7. The device according to claim 5, wherein
the third circuit includes a second switch element between the first power line and the first circuit,
a control signal for the second switch element is different from a control signal for the first switch element.

8. The device according to claim 5, wherein
the fourth circuit includes a second switch element connected in parallel to a path including the first resistor element and the first switch element.

9. The device according to claim 8, wherein
the third circuit supplies the first voltage to the first circuit in a second period,
in a third period between the first period and the second period,
the second switch element is which is an on-state, and
the fourth circuit supplies the first voltage to the second circuit via the second switch element, and
the second circuit takes in the first data from the first circuit by an operation property of the second circuit based on the first voltage.

10. The device according to claim 9, wherein
in a first portion of the third period, the first and second switch elements are which is in an on-state.

11. The device according to claim 8, wherein
in the first period, the first switch element is which is in an on-state, and the second switch element is which is in an off-state.

12. The device according to claim 8, wherein
in the second period when the third circuit supplies the first voltage to the first circuit, the first and second switch elements which are in an off-state.

13. The device according to claim 8, wherein
the third circuit includes a third switch element between the first power line and the first circuit, and
the third switch element is turned on or off based on a control signal different from those of the first and second switch elements.

14. The device according to claim 1, wherein
an absolute value of the first voltage on the first power line is smaller than an absolute value of the second voltage supplied to the second circuit from the first resistor element
the absolute value of the second voltage is equal to or greater than an absolute value of a threshold voltage of the second circuit.

15. The device according to claim 14, wherein
the second voltage is lower than the first voltage by voltage drop due to the resistor element.

16. The device according to claim 1, further comprising:
a second power line to which a third voltage is applied;
a fifth circuit between the first circuit and the second power supply line, the fifth circuit capable of shutting off a supply of the second voltage to the first circuit; and
a sixth circuit including a second resistor element, the second resistor element connected between the second power line and the second circuit,
wherein the sixth circuit supplies the third voltage to the second circuit via the second resistor element in the first period.

17. A semiconductor integrated circuit device comprising:
a first power line to which a first voltage is applied;
a first circuit operating based on a first data;
a second circuit capable of holding the first data;
a first transistor between the first power supply line and the first circuit, the first transistor capable of shutting off a supply of the first voltage to the first circuit; and
a second transistor between the first power supply line and the second circuit,
wherein
the first transistor shuts off the supply of the first voltage to the first circuit by a first control signal of a first level,
the first transistor supplies the first voltage to the first circuit by the first control signal of a second level,
in a first period when the first transistor shut off the supply of the first voltage to the first circuit, the second transistor operates by a second control signal of a third level between the first level and the second level,
the second transistor operated by the second control signal of the third level supplies second voltage to the second circuit from the first power line,
an absolute value of the first voltage is a first value,
an absolute value of the second voltage is a second value smaller than the first value, and
the second value is equal to or greater than an absolute value of a threshold voltage of the second circuit.

18. The device according to claim 17, wherein
in a second period when the first transistor supplies the first voltage to the first circuit, the second transistor operated by the second control signal of the first level shuts off a supply of the first voltage to the second circuit.

19. The device according to claim 17, wherein
the first transistor supplies the first voltage to the first circuit in a second period,
in the third period between the first period and the second period,
the second transistor operated by the second control signal of the second level supplies the first voltage to the second circuit,
the second circuit takes in the first data from the first circuit by an operation property of the second circuit based on the first voltage.

20. The device according to claim 17, wherein
a current drive ability of the second transistor is equal to a current drive ability of the first transistor.
